(19) United States
(12) Patent Application Publication
(10) Pub. No.: US 2026/0032903 A1
(43) Pub. Date: Jan. 29, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: HYUN-MOOK CHOI, Suwon-si (KR); Taeyoung Kim, Suwon-si (KR); Kumhyo Kang, Suwon-si (KR); Chae Lyoung Kim, Suwon-si (KR)

(73) Assignee: Samsung Electronics Co., Ltd., Suwon-si (KR)

(21) Appl. No.: 19/098,250

(22) Filed: Apr. 2, 2025

(30) Foreign Application Priority Data
Jul. 23, 2024 (KR) 10-2024-0097480

(51) Int. Cl. H10B 41/41; G11C 5/06; G11C 16/04; H01L 23/00; H01L 25/18; H10B 41/10; H10B 41/27; H10B 41/35; H10B 43/10; H10B 43/27; H10B 43/35; H10B 43/40; H10B 80/00; H10D 80/30

(52) U.S. Cl. CPC H10B 41/41; G11C 5/063; G11C 16/0483; H01L 24/08; H01L 25/18; H10B 41/10; H10B 41/27; H10B 41/35; H10B 43/10; H10B 43/27; H10B 43/35; H10B 43/40; H10B 80/00; H10D 80/30; H01L 24/32; H01L 24/48; H01L 2224/08145; H01L 2224/32145; H01L 2224/32225; H01L 2224/48147; H01L 2224/48227; H01L 2225/06506; H01L 2225/0651; H01L 2225/06524; H01L 2225/06562; H01L 2924/1438

(57) ABSTRACT

Provided is a semiconductor device including a peripheral circuit structure comprising peripheral circuits and a cell array structure overlapping the peripheral circuit structure and comprising first and second cell array regions and a connection region therebetween in a first direction, the cell array structure including a buried insulating pattern in the connection region, the buried insulating pattern having first and second side surfaces facing each other in the first direction and a third side surface connecting the first and second side surfaces, a stack including vertically stacked conductive patterns, each of the conductive patterns including a horizontal portion parallel to the first direction and a pad portion inclined with respect to the horizontal portion, and cell contact plugs connected to the pad portions of the conductive patterns, respectively, and the pad portion of each conductive pattern being on the first, second, and third side surfaces of the buried insulating pattern.

### CROSS-REFERENCE TO RELATED APPLICATIONS

This application claims priority to Korean Patent Application No. 10-2024-0097480 filed on Jul. 23, 2024, in the Korean Intellectual Property Office, the disclosure of which is incorporated by reference herein in its entirety.

### BACKGROUND

Embodiments of the present disclosure relate to a semiconductor device and an electronic system including the same.

A semiconductor device capable of storing a large amount of data in an electronic system which may need data storage is needed. An electronic system that is used to store data includes a semiconductor device capable of storing a large amount of data. For example, as an approach to increase data storage capacity of the semiconductor device, a semiconductor device has been suggested to include three-dimensionally arranged memory cells instead of two-dimensionally arranged memory cells.

### SUMMARY

One or more embodiments provide a semiconductor device with improved reliability and integration.

One or more embodiments also provide an electronic system including the semiconductor device.

The object of the present disclosure is not limited to the problems mentioned above, and other problems not mentioned may be clearly understood by those skilled in the art from the description below.

According to an aspect of one or more embodiments, there is provided a semiconductor device including a peripheral circuit structure including peripheral circuits, and a cell array structure overlapping the peripheral circuit structure and including a first cell array region, a second cell array region, and a connection region between the first cell array region and the second cell array region in a first direction, wherein the cell array structure includes a buried insulating pattern in the connection region, the buried insulating pattern including a first side surface and a second side surface facing each other in the first direction and a third side surface connecting the first side surface and the second side surface, a stack in the first cell array region, the second cell array region, and the connection region, the stack including conductive patterns stacked in a vertical direction, each conductive pattern of the conductive patterns including a horizontal portion parallel to the first direction and a pad portion inclined with respect to the horizontal portion, and cell contact plugs connected to the pad portion of each conductive pattern of the conductive patterns, respectively, wherein the pad portion of each conductive pattern of the conductive patterns is on the first side surface of the buried insulating pattern, the second side surface of the buried insulating pattern, and the third side surface of the buried insulating pattern, wherein the pad portion of each conductive pattern of the conductive patterns are spaced apart from each other by a first space in the first direction, and wherein the cell contact plugs are spaced apart from each other by a second space greater than the first space in the first direction.

According to another aspect of one or more embodiments, there is provided a semiconductor device including a first cell array structure and a second cell array structure including a first cell array region, a second cell array region, and a connection region between the first cell array region and the second cell array region in a first direction, and a peripheral circuit structure between the first cell array structure and the second cell array structure in a second direction perpendicular to the first direction, wherein each of the first cell array structure and the second cell array structure includes a buried insulating pattern in the connection region, the buried insulating pattern including a first side surface and a second side surface facing each other in the first direction and a third side surface connecting the first side surface and the second side surface, a stack including conductive patterns stacked in the first cell array region, the second cell array region, and the connection region in the second direction, each conductive pattern of the conductive patterns including a horizontal portion parallel to the first direction and a pad portion inclined with respect to the horizontal portion, vertical structures penetrating the stack, bit lines crossing the stack and connected to the vertical structures, cell contact plugs respectively connected to the pad portions of the conductive patterns, and input/output contact plugs penetrating the buried insulating pattern, wherein the peripheral circuit structure includes a first sub-peripheral circuit layer including first high-voltage circuits on a first semiconductor substrate and second bonding pads connected to the first high-voltage circuits and directly bonded to first bonding pads of the first cell array structure, a second sub-peripheral circuit layer including second high-voltage circuits on a second semiconductor substrate and fourth bonding pads connected to the second high-voltage circuits and directly bonded to third bonding pads of the second cell array structure, and a third sub-peripheral circuit layer including low-voltage circuits on a third semiconductor substrate between the first sub-peripheral circuit layer and the second sub-peripheral circuit layer, and wherein the cell contact plugs are spaced apart from each other by a second space and the pad portions are spaced apart from each other by a first space that is less than the second space.

According to still another aspect of one or more embodiments, there is provided an electronic system including a peripheral circuit structure and a cell array structure including a first cell array region, a second cell array region, and a connection region between the first cell array region and the second cell array region on the peripheral circuit structure, and a controller electrically connected to a semiconductor device through an input/output pad and configured to control the semiconductor device, wherein the cell array structure includes a buried insulating pattern in the connection region, the buried insulating pattern including a first side surface and a second side surface facing each other in a first direction and a third side surface connecting the first side surface and the second side surface, a stack including conductive patterns stacked in a vertical direction in the first cell array region, the second cell array region, and the connection region, each conductive pattern of the conductive patterns including a horizontal portion parallel to the first direction and a pad portion inclined with respect to the horizontal portion, and cell contact plugs respectively connected to the pad portions of the conductive patterns, wherein the pad portion of each conductive pattern of the conductive patterns is on the first side surface of the buried insulating pattern, the second side surface of the buried insulating pattern, and the third side surface of the buried insulating pattern.

### BRIEF DESCRIPTION OF DRAWINGS

Embodiments will be more clearly understood from the following detailed description taken in conjunction with the accompanying drawings in which:

FIG. 1 is a block diagram of a semiconductor device according to one or more embodiments;

FIG. 2 schematically illustrates a semiconductor device according to one or

more embodiments;

FIG. 3 is a perspective view schematically illustrating a semiconductor device according to one or more embodiments;

FIG. 4 is a schematic cross-sectional view of a semiconductor device according to one or more embodiments;

FIGS. 5A and 5B are enlarged views of portions ‘P1’ and ‘P2’ of FIG. 4.

FIG. 6 is a plan view of a cell array structure of a semiconductor device according to one or more embodiments;

FIGS. 7A and 7B are cross-sectional views of a cell array structure of a semiconductor device according to one or more embodiments, illustrating cross-sections taken along lines I-I′ and II-II′ of FIG. 6;

FIGS. 8A and 8B are enlarged views of portion ‘P3’ of FIG. 7A;

FIGS. 9A and 9B are enlarged views of portions ‘P4’ and ‘P5’ of FIG. 7A;

FIG. 10 is a schematic cross-sectional view of a semiconductor device according to one or more embodiments;

FIG. 11 is a cross-sectional view of a cell array structure of a semiconductor device according to one or more embodiments, illustrating cross-sections taken along line I-I′ of FIG. 6;

FIGS. 12A and 12B are enlarged views of portions ‘P4’ and ‘P5’ of FIG. 11;

FIG. 13 is a perspective view schematically illustrating a semiconductor device according to one or more embodiments;

FIG. 14 is a cross-sectional view schematically illustrating a semiconductor device according to one or more embodiments;

FIG. 15 is a cross-sectional view schematically illustrating a semiconductor device according to one or more embodiments;

FIG. 16 is a perspective view schematically illustrating a semiconductor device according to one or more embodiments;

FIG. 17 is a cross-sectional view schematically illustrating a semiconductor device according to one or more embodiments;

FIGS. 18, 19, 20, 21, 22, 23, and 24 are cross-sectional views for explaining a method of manufacturing a semiconductor device according to one or more embodiments;

FIG. 25 is a diagram schematically illustrating an electronic system including a semiconductor device according to one or more embodiments;

FIG. 26 is a perspective view schematically illustrating an electronic system including a semiconductor device according to one or more embodiments and

FIGS. 27 and 28 are cross-sectional views schematically illustrating semiconductor packages according to one or more embodiments.

### DETAILED DESCRIPTION

Hereinafter, with reference to the drawings, a semiconductor device according to embodiments of the inventive concept and a method for manufacturing the same, and further, an electronic system including the same, will be described in detail. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

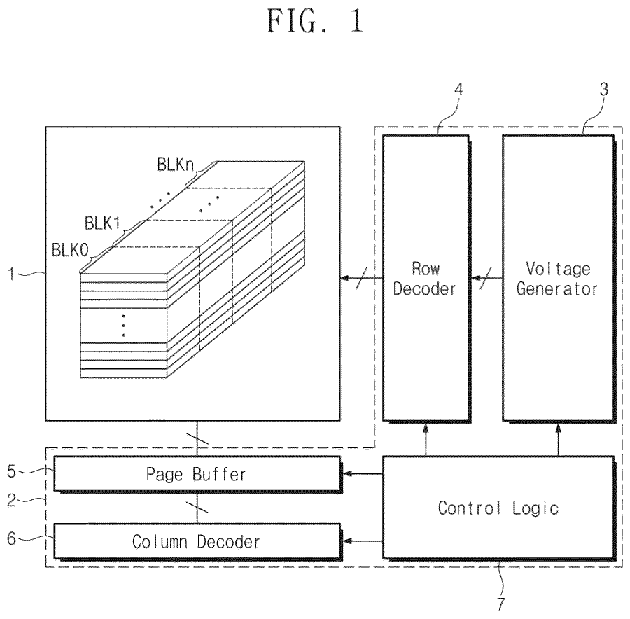

FIG. 1 is a block diagram of a semiconductor device according to one or more embodiments.

Referring to FIG. 1, the semiconductor device may include a memory cell array 1 and/or a peripheral circuit 2 for controlling the memory cell array 1. The peripheral circuit 2 may include a voltage generator 3, a row decoder 4, a page buffer 5, a column decoder 6, and/or control circuits 7.

The memory cell array 1 may include a plurality of memory blocks BLK0 to BLKn. Each of the memory blocks BLK0 to BLKn may include memory cells three-dimensionally disposed. For example, each the memory blocks BLK0 to BLKn may include structures stacked in a third direction D3 on a plane extending in a first direction D1 and a second direction D2 intersecting each other. The memory blocks BLK0 to BLKn may read or write data from the selected memory block in response to the corresponding block selection signal.

For example, the semiconductor device may be a vertical NAND flash memory device. In the case of the vertical NAND flash memory device, the memory blocks BLK0 to BLKn may include a plurality of NAND type cell strings.

As another example, the semiconductor device may be a variable resistance memory device. In the case of the variable resistive memory device, the memory blocks BLK0 to BLKn may include memory cells respectively disposed at intersections of word lines and bit lines. Here, each of the memory cells may include a resistive memory element. The resistive memory element may include perovskite compounds, transition metal oxides, phase-change materials, magnetic materials, ferromagnetic materials, or antiferromagnetic materials.

The voltage generator 3 may generate voltages (e.g., program voltage, read voltage, erase voltage, etc.) required for an internal operation of the memory cell array 1 under the control of the control circuit 7. For example, the voltage generator 3 may generate word line voltages, such as program voltage, read voltage, pass voltage, erase verification voltage, or program verification voltage. In addition, the voltage generator 3 may further generate a string selection line voltage and a ground selection line voltage based on a voltage control signal.

The row decoder 4 may select one of the memory blocks BLK0 to BLKn by decoding an address input from the outside, and may select one of the word lines of the selected memory block BLK0 to BLKn. In addition, the row decoder 4 may select one of the plurality of string selection lines SSL and one of the plurality of ground selection lines GSL.

For example, during a program operation, the row decoder 4 may apply a program voltage and a program verification voltage to the selected word line, and during a read operation, the row decoder 4 may apply a read voltage to the selected word line. For example, the row decoder 4 may include a word line driver and a ground selection line/string selection line driver. For example, the row decoder 4 may further include a pass transistor circuit, a block decoder, and a driving signal line decoder.

The page buffer 5 is connected to the memory cell array 1 via bit lines, and may read information stored in the memory cells. The page buffer 5 may operate as a write driver or a sense amplifier. For example, during a program operation, the page buffer 5 may store data in the memory cell by applying a voltage corresponding to data to be programmed to the bit line. For example, during a program verification operation or a read operation, the page buffer 5 may detect programmed data by detecting current or voltage via the bit line.

The column decoder 6 decodes an address input from the outside and selects one of the bit lines. The column decoder 6 may provide a data transmission path between the page buffer 5 and an external device (e.g., a memory controller).

The control circuit 7 may generate various control signals for programming data in the memory cell array 1, reading data from the memory cell array 1, or erasing data stored in the memory cell array 1 based on a command signal, an address signal, and a control signal.

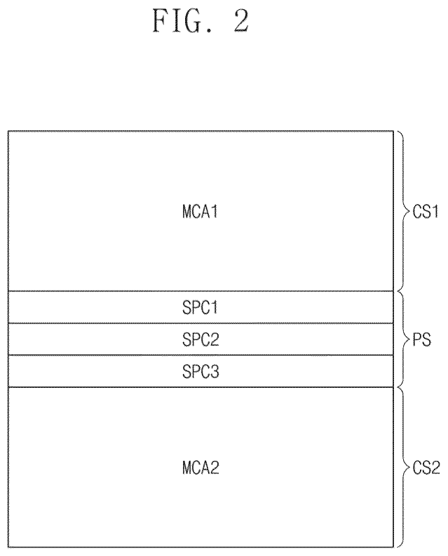

FIG. 2 schematically illustrates a semiconductor device according to one or more embodiments.

Referring to FIG. 2, a semiconductor device according to one or more embodiments may include a peripheral circuit structure PS and a first cell array structure CS1 and a second cell array structure CS2 vertically overlapping the peripheral circuit structure PS.

The first and second cell array structures CS1 and CS2 may include a memory cell array MCA1 and MCA2, respectively, including word lines, bit lines, and three-dimensionally disposed memory cells. The first and second cell array structures CS1 and CS2 may vertically overlap the peripheral circuit structure PS. The peripheral circuit structure PS and the first and second cell array structures CS1 and CS2 may be disposed to overlap each other, thereby improving integration density of the semiconductor device.

According to one or more embodiments, the peripheral circuit structure PS may be disposed between the first and second cell array structures CS1 and CS2. The peripheral circuit structure PS may include row and column decoders, a voltage generator, a page buffer, and control circuits described with reference to FIG. 1. The peripheral circuit structure PS may include peripheral circuits that are divided and disposed on a plurality of substrates of the semiconductor device.

For example, the peripheral circuit structure PS may include a first sub-peripheral circuit layer SPC1 adjacent to the first cell array structure CS1 and including high-voltage circuits, a second sub-peripheral circuit layer SPC2 disposed between the first sub-peripheral circuit layer SPC1 and a third sub-peripheral circuit layer SPC3 and including low-voltage circuits, and the third sub-peripheral circuit layer SPC3 adjacent to the second cell array structure CS2 and including high-voltage circuits.

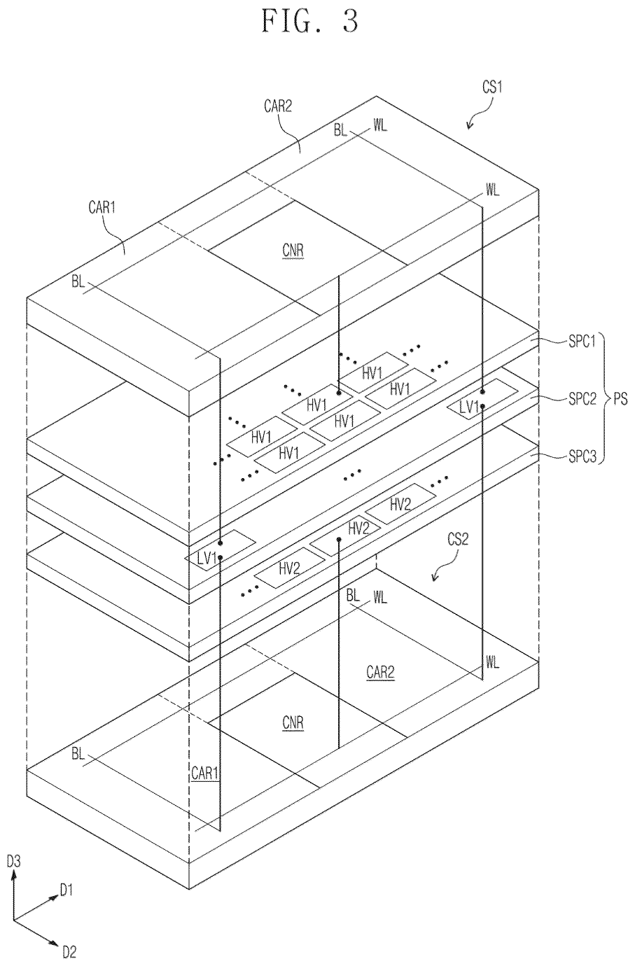

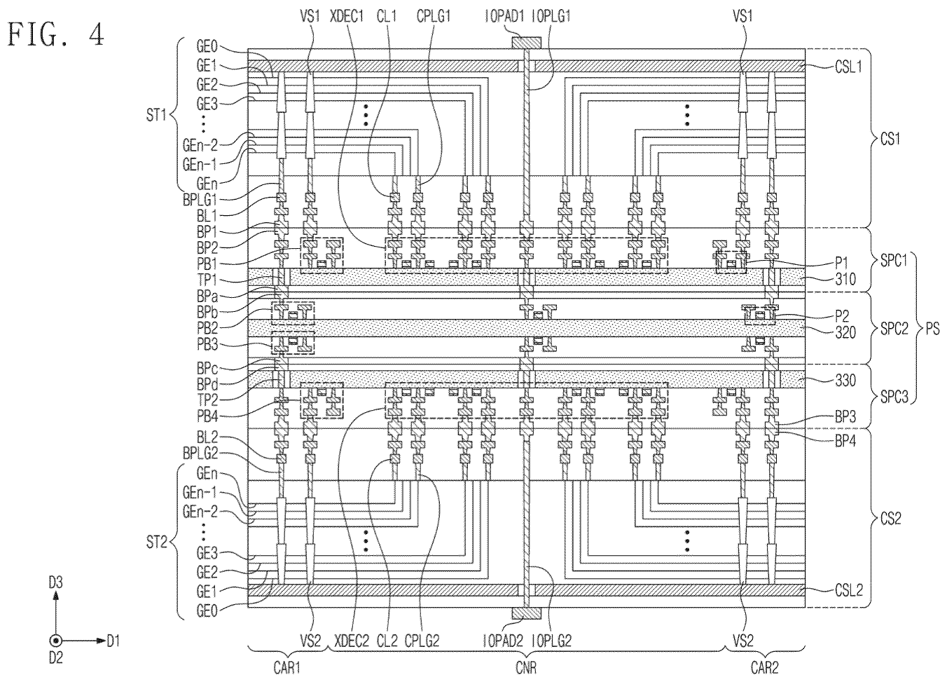

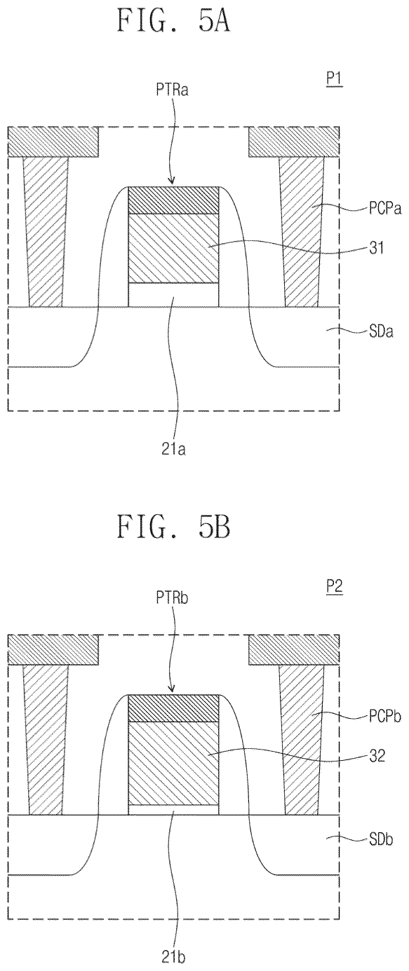

FIG. 3 is a perspective view schematically illustrating a semiconductor device according to one or more embodiments. FIG. 4 is a schematic cross-sectional view of a semiconductor device according to one or more embodiments. FIG. 5A and FIG. 5B are enlarged views of portions ‘P1’ and ‘P2’ of FIG. 4.

Referring to FIGS. 3 and 4, a semiconductor device according to one or more embodiments may include a peripheral circuit structure PS and first and second cell array structures CS1 and CS2 vertically overlapping the peripheral circuit structure PS.

According to one or more embodiments, each of the first and second cell array structures CS1 and CS2 may include a first cell array region CAR1 and a second cell array region CAR2 and a connection region CNR between the first cell array region CAR1 and the second cell array region CAR2. The memory blocks BLK described with reference to FIG. 1 may be provided in the first and second cell array regions CAR1 and CAR2, and connection wirings (e.g., cell contact plugs, penetration plugs, conductive lines, etc.) connecting a word line WL and the peripheral circuit structure PS may be provided in the connection region CNR.

For example, referring to FIG. 4, the first cell array structure CS1 may include a first common source line CSL1, a first stack ST1, first vertical structures VS1, first bit lines BL1, first conductive lines CL1, first bit line contact plugs BPLG1, first cell contact plugs CPLG1, and first input/output contact plugs IOPLG1. In addition, the first cell array structure CS1 may further include first bonding pads BP1 bonded to second bonding pads BP2 of the peripheral circuit structure PS.

According to one or more embodiments, the first stack ST1 may extend continuously in the first direction D1 in the first and second cell array regions CAR1 and CAR2 and the connection region CNR. The first stack ST1 may include conductive patterns GE0 to GEn alternately stacked in a third direction D3 (i.e., a vertical direction) perpendicular to the first and second directions D1 and D2 intersecting each other. Each of the conductive patterns GE0 to GEn may have pad portions positioned at the same distance from the first common source line CSL1 in the connection region CNR.

The first common source line CSL1 may be disposed on the first stack ST1 and may extend in the first direction D1 in the first and second cell array regions CAR1 and CAR2 and the connection region CNR. The first common source line CSL1 may be connected to the first vertical structures VS1 of the first and second cell array regions CAR1 and CAR2.

The first bit lines BL1 may be connected to the first vertical structures VS1 through the first bit line contact plugs BPLG1 in the first and second cell array regions CAR1 and CAR2. The first bit lines BL1 may be electrically connected to the first bonding pads BP1.

The first cell contact plugs CPLG1 may be respectively connected to pad portions of the conductive patterns GE0 to GEn in the connection region CNR. Each of the conductive patterns GE0 to GEn may be electrically connected to the first bonding pads BP1 through the first cell contact plugs CPLG1 and the first conductive lines CL1.

The first bonding pads BP1 may be disposed in the uppermost insulating layer of the first cell array structure CS1. The first bonding pads BP1 may be electrically connected to the first bit lines BL1 and the conductive patterns GE0 to GEn of the first stack ST1 through the connection wirings (e.g., conductive lines and conductive plugs). The first bonding pads BP1 may be formed of, for example, copper.

The first input/output contact plugs IOPLG1 may penetrate the first cell array structure CS1 in the connection region CNR. First input/output pads IOPAD1 may be disposed on the uppermost insulating layer of the first cell array structure CS1, and first input/output contact plugs IOPLG1 may be connected to the first input/output pads IOPAD1.

The second cell array structure CS2 may include components having substantially the same characteristics as the first cell array structure CS1. For example, the second cell array structure CS2 may include a second common source line CSL2, a second stack ST2, second vertical structures VS2, second bit lines BL2, second conductive lines CL2, second bit line contact plugs BPLG2, second cell contact plugs CPLG2, and second input/output contact plugs IOPLG2. In addition, the second cell array structure CS2 may further include third bonding pads BP3 that are bonded to fourth bonding pads BP4 of the peripheral circuit structure PS.

The fourth bonding pads BP4 may be disposed in the uppermost insulating layer of the second cell array structure CS2. The fourth bonding pads BP4 may be electrically connected to the second bit lines BL2 and the conductive patterns GE0 to GEn of the second stack ST2 through connection wirings (e.g., conductive lines and conductive plugs). The fourth bonding pads BP4 may be formed of, for example, copper.

The second input/output contact plugs IOPLG2 may penetrate the second cell array structure CS2 in the connection region CNR. Second input/output pads IOPAD2 may be disposed on the lowermost insulating layer of the second cell array structure CS2, and second input/output contact plugs IOPLG2 may be connected to the second input/output pads IOPAD2.

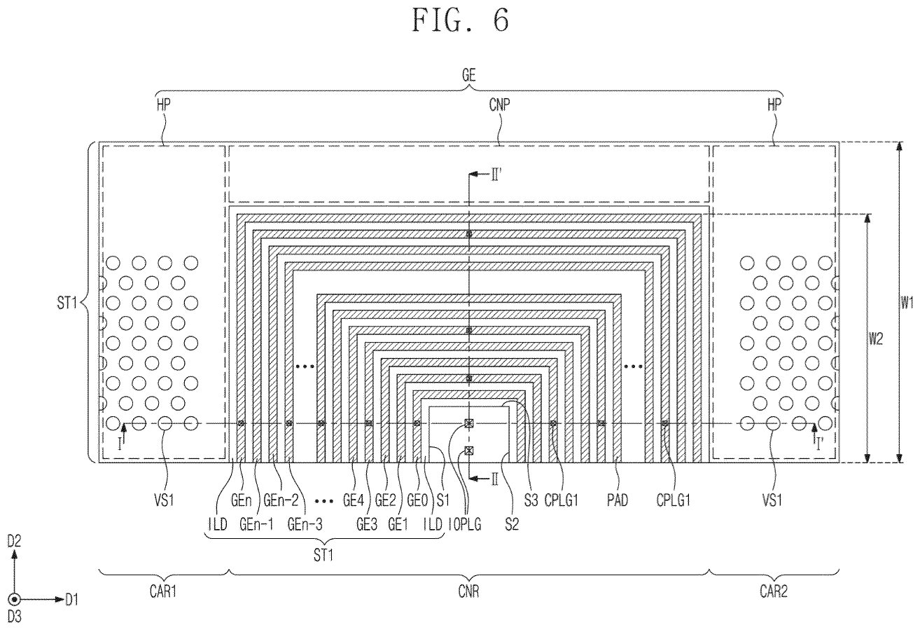

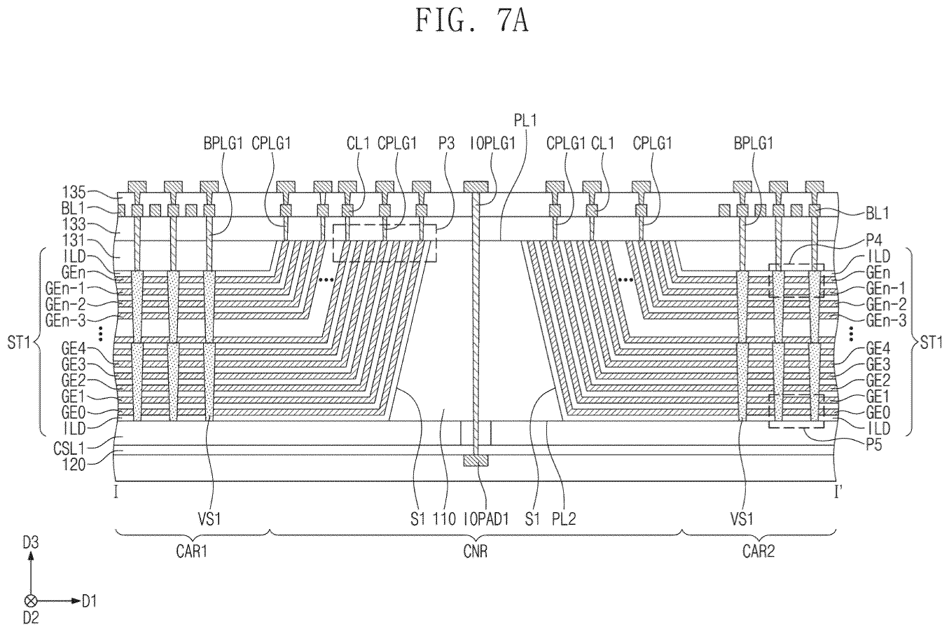

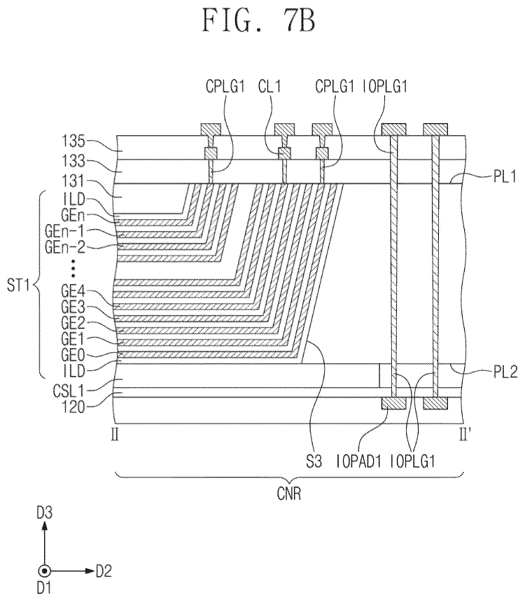

The first and second cell array structures CS1 and CS2 will be described in more detail with reference to FIGS. 6, 7A, and 7B.

According to one or more embodiments, the peripheral circuit structure PS may be disposed between the first and second cell array structures CS1 and CS2. As described above, the peripheral circuit structure PS may include a first sub-peripheral circuit layer SPC1, a second sub-peripheral circuit layer SPC2, and a third sub-peripheral circuit layer SPC3.

The first, second, and third sub-peripheral circuit layers SPC1, SPC2, and SPC3 may include at least one of the row and column decoders, the voltage generator, the page buffer, and the control circuits described with reference to FIG. 1.

According to one or more embodiments, the first sub-peripheral circuit layer SPC1 may include first high-voltage circuits HV1, and the first high-voltage circuits HV1 may be connected to the first cell array structure CS1. The second sub-peripheral circuit layer SPC2 may include low-voltage circuits LV, and the low-voltage circuits LV may be connected to the first and second cell array structures CS1 and CS2. The third sub-peripheral circuit layer SPC3 may include second high-voltage circuits HV2, and the second high-voltage circuits HV2 may be connected to the second cell array structure CS2.

The first and second high voltage circuits HV1 and HV2 may include transistors forming a portion of the pass transistors of the row decoder 4 and the page buffer 5 described with reference to FIG. 1. The low voltage circuits LV may include transistors forming a portion of the page buffer 5 with reference to FIG. 1.

For example, referring to FIG. 4, the first sub-peripheral circuit layer SPC1 may include a first semiconductor substrate 310, a first row decoder circuit XDEC1, a first page buffer circuit PB1, a first penetration plug TP1, first peripheral bonding pads BPa, and second bonding pads BP2.

In the first sub-peripheral circuit layer SPC1, the first row decoder circuit XDEC1 and the first page buffer circuit PB1 may include first high-voltage transistors PTRa integrated and provided on a first semiconductor substrate 310, as illustrated in FIG. 5A. The first high-voltage transistors PTRa may include a first gate insulating pattern 21a, a first gate electrode 31, and first source and drain regions SDa.

The first gate electrode 31 may be disposed on the first semiconductor substrate 310. The first gate insulating pattern 21a may be disposed between the first semiconductor substrate 310 and the first gate electrode 31, and first source and drain regions SDa may be provided in the first semiconductor substrate 310 on both side surfaces of the first gate electrode 31. In addition, first peripheral plugs PCPa may be connected to the first source and drain regions SDa.

The second bonding pads BP2 of the first sub-peripheral circuit layer SPC1 may be disposed in the uppermost insulating layer of the peripheral circuit structure PS. The second bonding pads BP2 may be connected to peripheral circuits through peripheral circuit wirings (e.g., conductive lines and conductive plugs). The second bonding pads BP2 may be formed of, for example, copper.

The first sub-peripheral circuit layer SPC1 may include the first peripheral bonding pads BPa in the insulating layer covering the back surface of the first semiconductor substrate 310. The first peripheral bonding pads BPa may be electrically connected to the first page buffer circuit PB1 on the first semiconductor substrate through the first penetration plugs TP1 penetrating the first semiconductor substrate 310.

The second sub-peripheral circuit layer SPC2 may include a second semiconductor substrate 320, a second page buffer circuit PB2, a third page buffer circuit PB3, and second and third peripheral bonding pads BPb and BPc.

The second page buffer circuit PB2 may be integrated and provided on an upper surface of the second semiconductor substrate 320, and the third page buffer circuit PB3 may be integrated and provided on a back surface of the second semiconductor substrate 320.

The second and third page buffer circuits PB2 and PB3 of the second sub-peripheral circuit layer SPC2 may include low-voltage transistors PTRb integrated and provided on the second semiconductor substrate 320, as illustrated in FIG. 5B.

The low-voltage transistors PTRb may include a second gate insulating pattern 21b, a second gate electrode 32, and second source and drain regions SDb. The second gate electrode 32 may be disposed on an upper surface or a back surface of the second semiconductor substrate 320. The second gate insulating pattern 21b may be disposed between the second semiconductor substrate 320 and the second gate electrode 32. The second gate insulating pattern 21b may be thinner than the first gate insulating pattern 21a.

The second peripheral bonding pads BPb may be disposed in the uppermost insulating layer of the second sub-peripheral circuit layer SPC2. The third peripheral bonding pads BPc may be disposed in the lowermost insulating layer of the second sub-peripheral circuit layer SPC2. The second and third peripheral bonding pads BPb and BPc may be connected to peripheral circuits through peripheral circuit wirings (e.g., conductive lines and conductive plugs). The second and third peripheral bonding pads BPb and BPc may be formed of, for example, copper.

The third sub-peripheral circuit layer SPC3 may include a third semiconductor substrate 330, a second row decoder circuit XDEC2, a fourth page buffer circuit PB4, a second penetration plug TP2, third peripheral bonding pads BPc, and fourth bonding pads BP4.

The second row decoder circuit XDEC2 and the fourth page buffer circuit PB4 of the third sub-peripheral circuit layer SPC3 may include the second high-voltage transistors integrated and provided on the third semiconductor substrate 330, as described with reference to FIG. 5A.

The fourth bonding pads BP4 of the third sub-peripheral circuit layer SPC3 may be disposed in the lowest insulating layer of the peripheral circuit structure PS. The fourth bonding pads BP4 may be connected to peripheral circuits through peripheral circuit wirings (e.g., conductive lines and conductive plugs). The fourth bonding pads BP4 may be formed of, for example, copper.

The third sub-peripheral circuit layer SPC3 may include third peripheral bonding pads BPc in an insulating layer covering a back surface of the third semiconductor substrate 330. The third peripheral bonding pads BPc may be electrically connected to the third page buffer circuit PB3 on the third semiconductor substrate 330 through second penetration plugs TP2 penetrating the third semiconductor substrate 330.

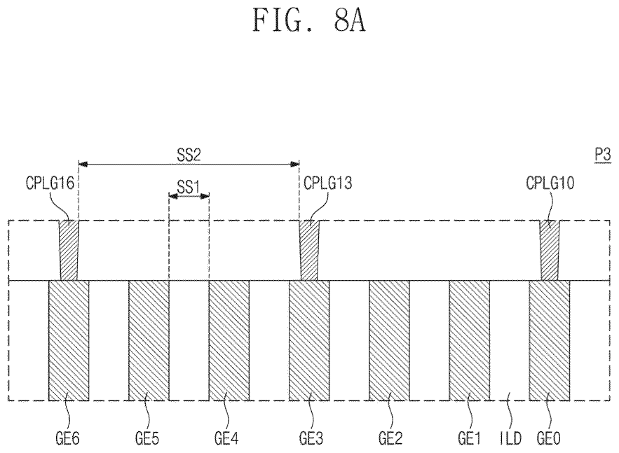

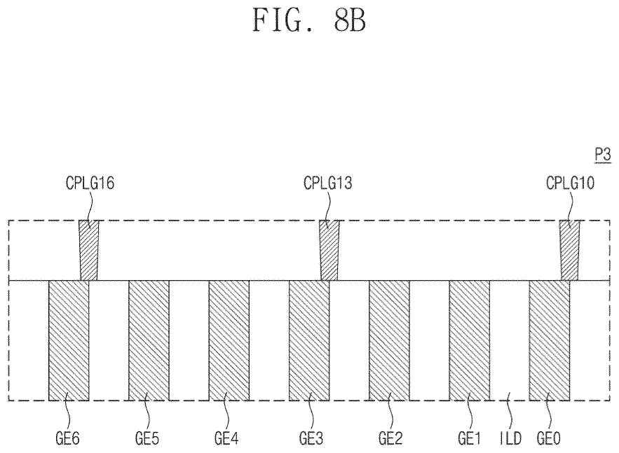

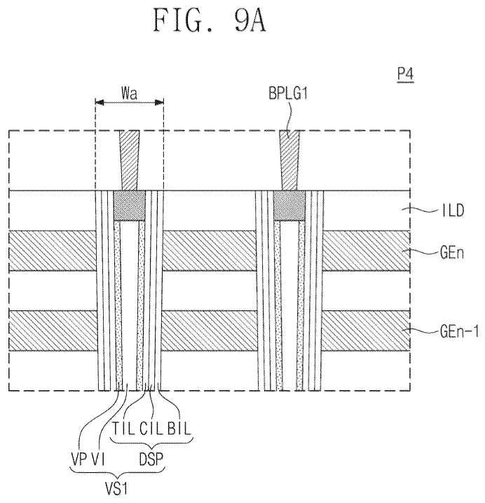

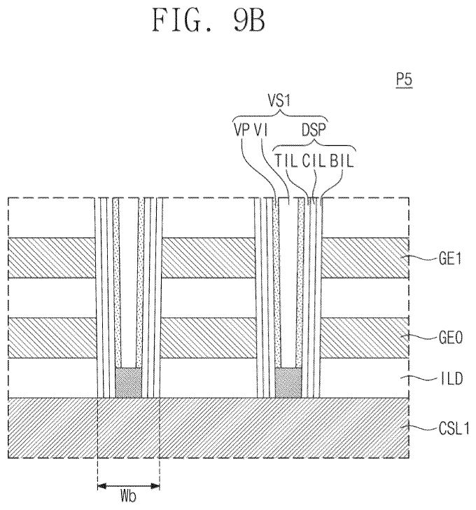

FIG. 6 is a plan view of a cell array structure of a semiconductor device according to one or more embodiments. FIG. 7A and FIG. 7B are cross-sectional views of a cell array structure of a semiconductor device according to one or more embodiments, illustrating cross-sections taken along lines I-I′ and II-II′ of FIG. 6. FIG. 8A and FIG. 8B are enlarged views of portion ‘P3’ of FIG. 7A. FIG. 9A and FIG. 9B are enlarged views of portions ‘P4’ and ‘P5’ of FIG. 7A.

Referring to FIGS. 6, 7A, and 7B, a cell array structure of a semiconductor device may include, as described above, first and second cell array regions CAR1 and CAR2 and a connection region CNR between the first and second cell array regions CAR1 and CAR2 in the first direction D1.

The cell array structure may include a common source line CSL1, a buried insulating pattern 110, a stack ST1, vertical structures VS1, bit lines BL1, bit line contact plugs BPLG1, cell contact plugs CPLG1, and input/output contact plugs IOPLG1.

The stack ST1 and the buried insulating pattern 110 may be disposed on the common source line CSL1. The common source line CSL1 may extend from the first cell array region CAR1 to the connection region CNR and the second cell array region CAR2.

The common source line CSL1 may include at least one of, for example, a doped semiconductor (e.g., doped silicon), a metal (e.g., tungsten, molybdenum, nickel, copper, aluminum, etc.), a conductive metal nitride (e.g., titanium nitride, tantalum nitride, etc.), or a transition metal (e.g., titanium, tantalum, etc.).

According to one or more embodiments, the buried insulating pattern 110 may be provided in the connection region CNR and may be disposed on the common source line CSL1. The buried insulating pattern 110 may have a first side surface S1 and a second side surface S2 facing each other in the first direction D1, and a third side surface S3 connecting the first and second side surfaces S1 and S2. The first, second, and third side surfaces S1, S2, and S3 of the buried insulating pattern 110 may have an inclination of 90 to 130 degrees with respect to a horizontal portion HP of each conductive pattern GE0 to GEn.

The buried insulating pattern 110 may have a first plane PL1 and a second plane PL2 opposite to the first plane PL1. The first plane PL1 of the buried insulating pattern 110 may be parallel to the first and second directions D1 and D2 and may be disposed closer to the peripheral circuit structure PS (refer to FIG. 4) than the second plane PL2. The second plane PL2 of the buried insulating pattern 110 may be adjacent to the common source line CSL1. A width of the buried insulating pattern 110 at the first plane PL1 may be less than a width at the second plane PL2 thereof.

The first, second, and third side surfaces S1, S2, and S3 of the buried insulating pattern 110 may be surrounded by pad portions PAD of each conductive pattern GE0 to GEn. For example, the by pad portions PAD of each conductive pattern GE0 to GEn may be provided on the first, second, and third side surfaces S1, S2, and S3 of the buried insulating pattern 110. The pad portions PAD of the conductive patterns GE0 to GEn may be parallel to the first, second, and third side surfaces S1, S2, and S3 of the buried insulating pattern 110. The first plane PL1 of the buried insulating pattern 110 may be substantially coplanar with upper surfaces of the pad portions PAD of the conductive patterns GE0 to GEn.

The buried insulating pattern 110 may include, for example, silicon oxide, silicon nitride, silicon oxynitride, and/or a low-k material. For example, the buried insulating pattern 110 may include high-density plasma oxide (HDP oxide) or TetraEthylOrthoSilicate (TEOS).

The stack ST1 may be provided on and surround three side surfaces S1, S2, and S3 of the buried insulating pattern 110 and may extend in the first direction D1. The stack ST1 may have a first width W1 in the second direction D2, and the buried insulating pattern 110 may have a width less than the first width W1 in the second direction D2.

The stack ST1 may include conductive patterns GE0 to GEn and insulating layers ILD alternately stacked in the third direction D3 (i.e., a vertical direction) that is perpendicular to the first and second directions D1 and D2 that intersect each other. The conductive patterns GE0 to GEn may include at least one of, for example, a doped semiconductor (e.g., doped silicon), a metal (e.g., tungsten, copper, aluminum, etc.), a conductive metal nitride (e.g., titanium nitride, tantalum nitride, etc.), or a transition metal (e.g., titanium, tantalum, etc.). The insulating layer ILD may include a silicon oxide layer and/or a low-k layer.

Although FIG. 6 illustrates one stack ST1, the stack ST1 may be provided in the plural, and a plurality of stacks ST1 may be disposed spaced apart from each other in the second direction D2.

In one or more embodiments, each of the conductive patterns GE0 to GEn may include horizontal portions HP, a connection portion CNP, and a pad portion PAD. The horizontal portions HP may be provided in the first and second cell array regions CAR1 and CAR2 and be parallel to a plane defined by the first and second directions D1 and D2. The connection portion CNP may be provided on the connection region CNR and connect the horizontal portions HP of the first and second cell array regions CAR1 and CAR2. The pad portion PAD may be vertically extended from the horizontal portions HP and the connection portion CNP and be provided in the connection region CNR.

The horizontal portions HP of the conductive patterns GE0 to GEn may decrease in length in the first direction D1 as the horizontal portions HP approach the peripheral circuit structure PS (refer to FIG. 4).

In one or more embodiments, the pad portions PAD of the conductive patterns GE0 to GEn may have a certain inclination angle with respect to the horizontal portions HP, and upper surfaces of the pad portions PAD may be substantially coplanar and may be positioned at substantially the same level. The upper surfaces of the pad portions PAD may be positioned at a higher level than the uppermost horizontal portion HP in the first and second cell array regions CAR1 and CAR2 in the vertical direction. In one or more embodiments, the pad portions PAD may have an inclination of about 90 degrees to 130 degrees with respect to the horizontal portions HP.

The pad portions PAD of the conductive patterns GE0 to GEn may have a maximum second width W2 in the second direction D2, and the second width W2 may be less than the first width W1 of the stack ST1.

For example, the pad portion PAD of each conductive pattern GE0, GE1 . . . , or GEn may be provided on and surround at least three side surfaces S1, S2, and S3 of the buried insulating pattern 110 and may be parallel to the three side surfaces S1, S2, and S3. For example, the pad portion PAD of each conductive pattern GE0, GE1 . . . , or GEn may include a first portion adjacent to the first side surface S1 of the buried insulating pattern 110, a second portion adjacent to the second side surface S2 of the buried insulating pattern 110, and a third portion adjacent to the third side surface S3 of the buried insulating pattern 110. In each conductive pattern GE0, GE1 . . . , or GEn, a cell contact plug CPLG1 may be connected to one of the first, second, and third portions of the pad portion PAD. Accordingly, one conductive pattern GE0, GE1 . . . , or GEn may be connected to one cell contact plug CPLG1.

For example, referring to FIGS. 7A, 8A, and 8B, the stack ST1 may include n conductive patterns GE0 to GEn, and more particularly, may include a first conductive pattern GE0 that is most adjacent to the common source line CSL1, and second, third, fourth, fifth, and sixth conductive patterns GE1, GE2, GE3, GE4, GE5 . . . may be sequentially stacked on the first conductive pattern GE0. In addition, the first to ‘n’-th conductive patterns GE0 to GEn may be sequentially stacked from the side surfaces S1, S2, and S3 of the buried insulating pattern 110.

As illustrated in FIG. 8A, the conductive patterns GE0 to GEn may be spaced apart from each other in the first direction D1 and the second direction D2 with a constant first spacing SS1. The first spacing SS1 may correspond to a thickness of each insulating layer ILD. The cell contact plugs CPLG1 (CPLG10, CPLG13, and CPLG16) may be disposed at a second spacing SS2 greater than the first spacing SS1 between the pad portions PAD adjacent to each other in the first direction D1. Accordingly, as illustrated in FIG. 8B, even when the cell contact plugs CPLG1 (CPLG10, CPLG13, and CPLG16) are misaligned or increase in size, a process margin may be secured.

According to one or more embodiments, a plurality of vertical structures VS1 may vertically penetrate the stack ST1 in the first and second cell array regions CAR1 and CAR2. For example, the plurality of vertical structures VS1 may penetrate the horizontal portions HP of the conductive patterns GE0 to GEn in the third direction D3.

The vertical structures VS1 may be disposed in a matrix form or in a zigzag form when viewed in a plan view. Each of the vertical structures VS1 may include a vertical channel formed of a semiconductor material. Each of the vertical structures VS1 may include a lower portion penetrating a lower portion of the stack ST1 and an upper portion penetrating an upper portion of the stack ST1. Each of the lower and upper portions of each vertical structure VS1 may have a width that gradually increases as a distance from the common source line CSL1 increases.

For example, referring to FIGS. 9A and 9B, each of the vertical structures VS1 may have an upper surface adjacent to the bit line contact plugs BPLG1 and a lower surface adjacent to the common source line CSL1. Each of the vertical structures VS1 may have a maximum width Wa at the upper surface thereof and a minimum width Wb at the lower surface thereof.

Each of the vertical structures VS1 may include a vertical channel VP, a vertical insulating pillar VI, and a data storage pattern DSP.

The vertical channel VP may have, for example, a cylindrical shape (e.g., a macaroni shape or a pipe shape whose top and bottom ends are closed). The vertical channel VP may have an inner sidewall defining an internal space and an outer sidewall adjacent to the stack ST1. The vertical channel VP may surround the outer sidewall of the vertical insulating pillar VI.

The vertical channel VP may include a semiconductor material such as, for example, silicon (Si), germanium (Ge), or a mixture thereof. The vertical channel VP including the semiconductor material may be used as channels of memory cell transistors.

The vertical channel VP may have a source conductive pad contacting a common source line CSL1 at a lower end thereof, and may have a bit line conductive pad in contact with a bit line contact plug BPLG1 at the lower end thereof. The source conductive pad and the bit line conductive pad may be formed of an undoped semiconductor material, a doped semiconductor material, or a conductive material.

The data storage pattern DSP may extend in a vertical direction and be provided on and surround the outer sidewall of each vertical channel VP. The data storage pattern DSP may have a cylindrical shape (e.g., a macaroni shape or a pipe shape whose top and bottom ends are opened). The data storage pattern DSP may be formed of one thin layer or a plurality of thin layers. In some embodiments of the inventive concept, the data storage pattern DSP may be a data storage layer of a NAND flash memory device, and may include a tunnel insulating layer TIL, a charge storage layer CIL, and a blocking insulating layer BIL sequentially stacked on the outer sidewall of the vertical channel VP. For example, the charge storage layer CIL may be an insulating layer including a trap insulating layer, a floating gate electrode, or conductive nano dots.

Referring again to FIGS. 6, 7A, and 7B, a first insulating layer 131 may be disposed on the stack ST1 in the first and second cell array regions CAR1 and CAR2. The first insulating layer 131 may cover upper surfaces of the vertical structures VS1. The upper surface of the first insulating layer 131 may be substantially coplanar with the upper surfaces of the pad portions PAD of the conductive patterns GE0 to GEn.

A second insulating layer 133 may cover the first insulating layer 131, the pad portions PAD of the conductive patterns GE0 to GEn, and the first plane PL1 of the buried insulating pattern 110.

The bit lines BL1 may be disposed on the second insulating layer 133 in each of the first and second cell array regions CAR1 and CAR2. The bit lines BL1 may extend in the second direction D2 across the stack ST1. The bit lines BL1 may be electrically connected to the vertical structures VS1 through the bit line contact plugs BPLG1.

The bit line contact plugs BPLG1 may be connected to the vertical structures VS1 by penetrating the first and second insulating layers 131 and 133, respectively.

The cell contact plugs CPLG1 may be connected to the pad portions PAD of the conductive patterns GE0 to GEn by penetrating the second insulating layer 133, respectively. The upper surfaces of the pad portions PAD of the conductive patterns GE0 to GEn may be coplanar, and thus the cell contact plugs CPLG1 may have substantially the same length.

In addition, the pad portions PAD of the conductive patterns GE0 to GEn may be provided on and surround the first, second, and third side surfaces S1, S2, and S3 of the buried insulating pattern 110, and thus the cell contact plugs CPLG1 may be disposed adjacent to one of the first, second, and third side surfaces S1, S2, and S3.

For example, referring to FIG. 6, the cell contact plugs CPLG1 may include first contacts connected to first portions of the pad portions, second contacts connected to second portions of the pad portions, and third contacts connected to third portions of the pad portions. Here, the first portions of the pad portions may be adjacent to the first side surface S1 of the buried insulating pattern 110, the second portions of the pad portions may be adjacent to the second side surface S2 of the buried insulating pattern 110, and the third portions of the pad portions may be adjacent to the third side surface S3 of the buried insulating pattern 110.

The first contacts of the cell contact plugs CPLG1 may be disposed in the connection region CNR adjacent to the first cell array region CAR1, and may be spaced apart from each other by a certain distance in the first direction D1. The second contacts of the cell contact plugs CPLG1 may be disposed in the connection region CNR adjacent to the second cell array region CAR2, and may be spaced apart from each other by a certain distance in the first direction D1. The third contacts of the cell contact plugs CPLG1 may be spaced apart from each other by a certain distance in the second direction D2.

For example, the cell contact plugs CPLG1 may be disposed to be connected to each of the three conductive patterns in the first, second, or third portions of the pad portions PAD.

For example, the first to ‘n’-th conductive patterns GE0 to GEn may be sequentially stacked ‘n’ times from the side surfaces S1, S2, and S3 of the buried insulating pattern 110, and the first contacts of the cell contact plugs CPLG1 may be connected to the first, fourth, seventh, and n−2-th conductive patterns GE0, GE3, GE6, . . . , GEn−2, respectively. In addition, the second contacts of the cell contact plugs CPLG1 may be connected to the third, sixth, ninth, and n−2-th conductive patterns GE2, GE5, GE8, . . . , GEn, respectively, and the third contacts of the cell contact plugs CPLG1 may be connected to the second, fifth, eighth, and n−2th conductive patterns GE1, GE4, GE7, . . . , GEn−1, respectively.

The conductive lines CL1 may be disposed on the second insulating layer 133 in the connection region CNR, and the conductive lines CL1 may be connected to the cell contact plugs CPLG1.

Furthermore, according to one or more embodiments, the input/output contact plugs IOPLG1 may penetrate the buried insulating pattern 110 at a center of the connection region CNR. The input/output contact plugs IOPLG1 may penetrate the common source line CSL1 and be connected to the input/output pads IOPAD1 disposed on a first capping insulating layer 120 covering the common source line CSL1. A penetration insulating pattern may be disposed between the input/output contact plugs IOPLG1 and the common source line CSL1, and thus, the input/output contact plugs IOPLG1 may be insulated from the common source line CSL1.

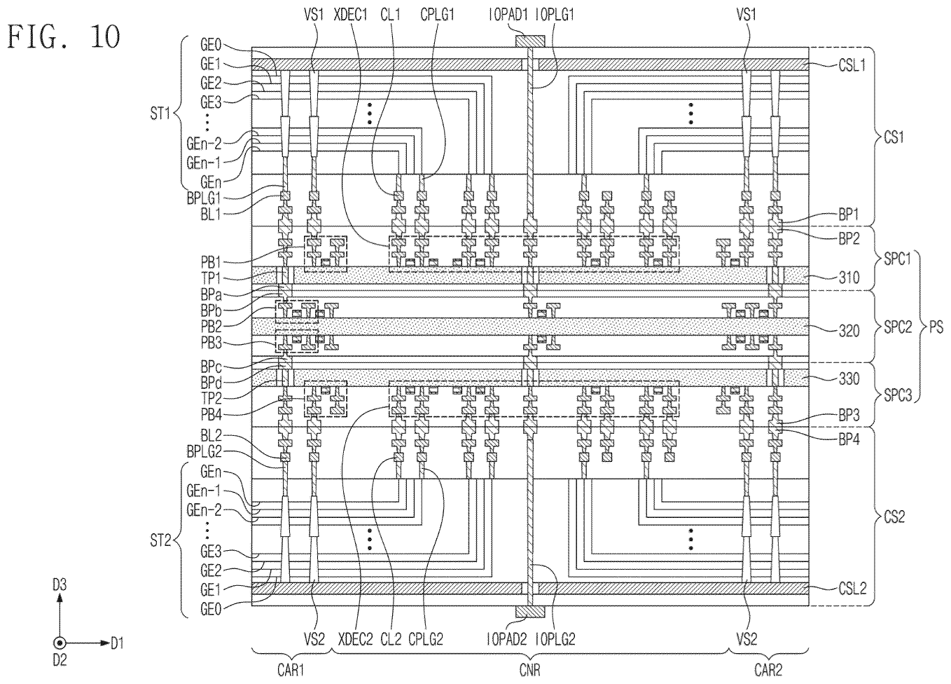

Hereinafter, embodiments a will be described with reference to FIGS. 10 to 17. For the sake of brevity, descriptions of technical features identical to those of the semiconductor device described above may be omitted, and differences between the embodiments will be described.

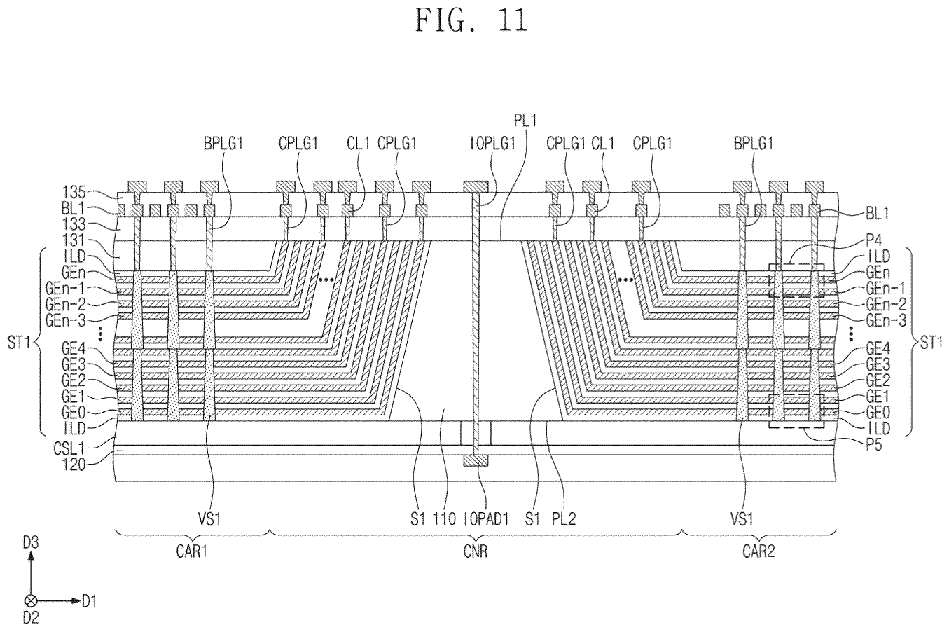

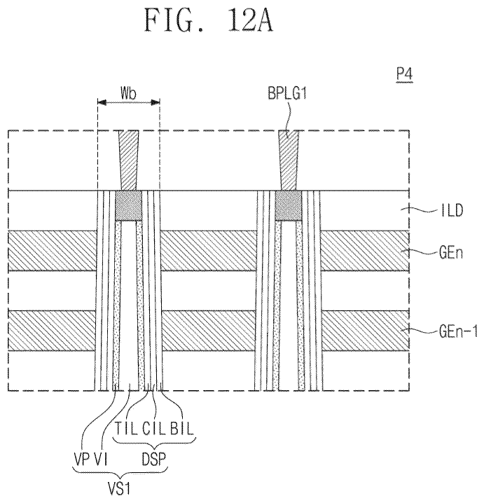

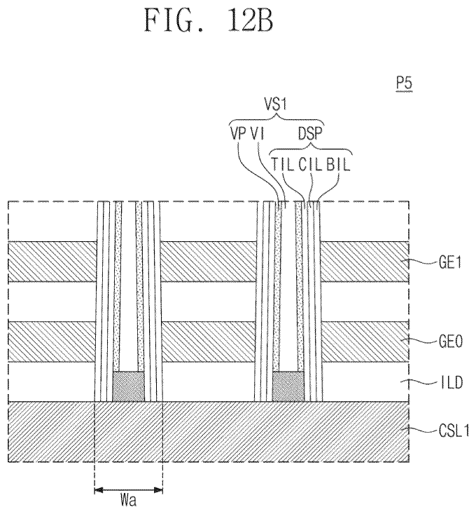

FIG. 10 is a schematic cross-sectional view of a semiconductor device according to one or more embodiments. FIG. 11 is a cross-sectional view of a cell array structure of a semiconductor device according to one or more embodiments, illustrating cross-sections taken along line I-I′ of FIG. 6. FIG. 12A and FIG. 12B are enlarged views of portions ‘P4’ and ‘P5’ of FIG. 11.

Referring to FIGS. 10 and 11, a semiconductor device may include a peripheral circuit structure PS, a first cell array structure CS1, and a second cell array structure CS2 vertically overlapping the peripheral circuit structure PS.

The peripheral circuit structure PS may include a first sub-peripheral circuit layer and a third sub-peripheral circuit layer SPC3 including high-voltage transistors, and a second sub-peripheral circuit layer SPC2 including low-voltage transistors, as described above.

Each of the first and second cell array structures CS1 and CS2 may include common source lines CSL1 and CSL2, buried insulating patterns 110 and 120, stacks ST1 and ST2, vertical structures VS1 and VS2, bit lines BL1 and BL2, bit line contact plugs BPLG1 and BPLG2, cell contact plugs CPLG1 and CPLG2, input/output contact plugs IOPLG1 and IOPLG2, and bonding pads BP1 and BP2, respectively, as described above.

According to this embodiment, each of the vertical structures VS1 may include a lower portion penetrating a lower portion of the stack ST1 and an upper portion penetrating an upper portion of the stack ST1. Each of the lower and upper portions of each vertical structure VS1 may have a width that gradually decreases as a distance from the common source line CSL1 increases. Accordingly, as illustrated in FIGS. 12A and 12B, each of the vertical structures VS1 may have a minimum width Wb at an upper surface adjacent to the bit line plug BPLG1 and a maximum width Wa at a lower surface adjacent to the common source line CSL1.

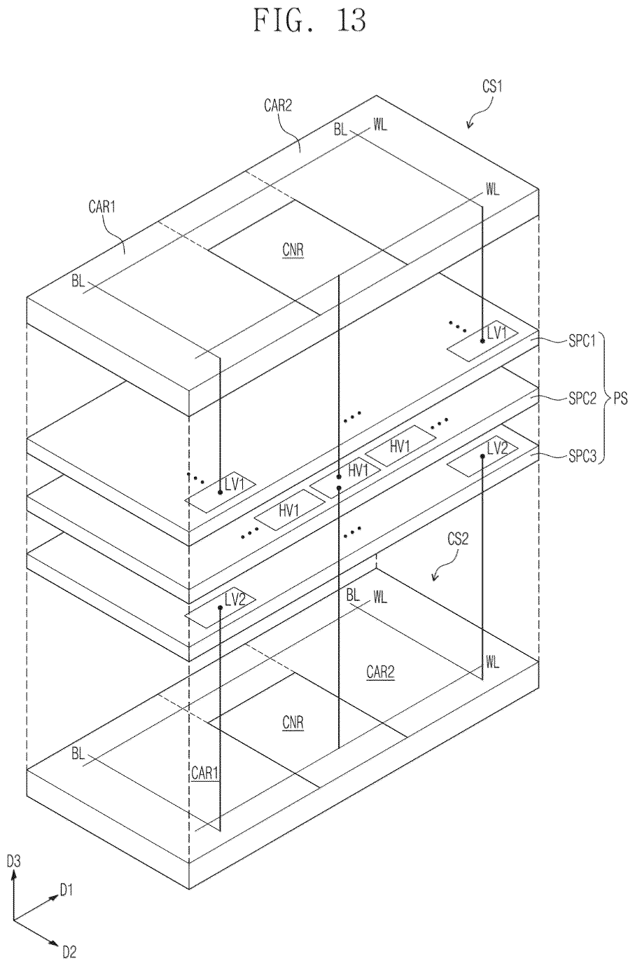

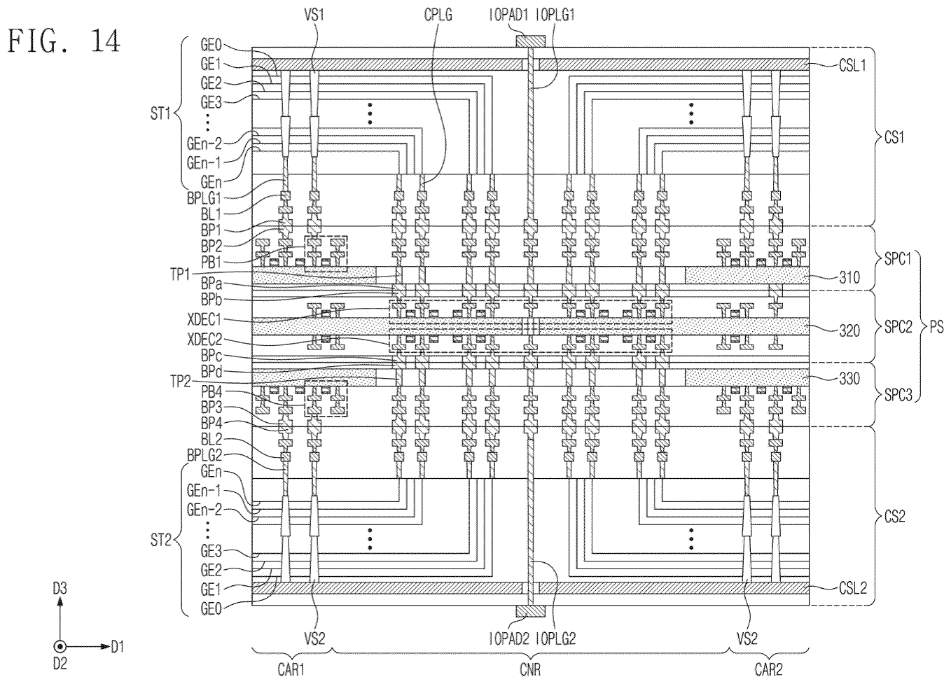

FIG. 13 is a perspective view schematically illustrating a semiconductor device according to one or more embodiments. FIG. 14 is a cross-sectional view schematically illustrating a semiconductor device according to one or more embodiments.

Referring to FIGS. 13 and 14, a semiconductor device may include a peripheral circuit structure PS, a first cell array structure CS1, and a second cell array structure CS2 vertically overlapping the peripheral circuit structure PS.

The peripheral circuit structure PS may include a first sub-peripheral circuit layer SPC1 and a third sub-peripheral circuit layer SPC3 including a first low-voltage circuit LV1 and a second low-voltage circuit LV2, and a second sub-peripheral circuit layer SPC2 including high-voltage circuits HV.

For example, the first sub-peripheral circuit layer SPC1 may include a first page buffer circuit PB1 integrated and provided on a first semiconductor substrate 310, and the first page buffer circuit PB1 may be connected to first bit lines BL1 of the first cell array structure CS1 through second bonding pads BP2. In addition, the first sub-peripheral circuit layer SPC1 may include first penetration plugs TP1 penetrating the first semiconductor substrate 310 in the connection region CNR. The first penetration plugs TP1 may be connected to the conductive patterns GE0 to GEn of the first cell array structure CS1 through the second bonding pads BP2. In addition, the first sub-peripheral circuit layer SPC1 may include first peripheral bonding pads BPa in an insulating layer covering a back surface of the first semiconductor substrate 310.

The second sub-peripheral circuit layer SPC2 may include a first row decoder circuit XDEC1 integrated and provided on a first surface of the second semiconductor substrate 320 and a second row decoder circuit XDEC2 integrated and provided on a second surface of the second semiconductor substrate 320. The second sub-peripheral circuit layer SPC2 may include a second page buffer circuit disposed on the first surface and connected to the first bit lines BL1 and a third page buffer circuit disposed on the second surface and connected to the second bit lines BL2.

The first row decoder circuit XDEC1 may be connected to the conductive patterns GE0 to GEn of the first cell array structure CS1 through the second peripheral bonding pads BPb. The second row decoder circuit XDEC2 may be connected to the conductive patterns GE0 to GEn of the second cell array structure CS2 through the third peripheral bonding pads BPc.

The third sub-peripheral circuit layer SPC3 may include a fourth page buffer circuit PB4 integrated and provided on a third semiconductor substrate 330, and the fourth page buffer circuit PB4 may be connected to second bit lines BL2 of the second cell array structure CS2 through third bonding pads BP3. In addition, the third sub-peripheral circuit layer SPC3 may include second penetration plugs TP2 penetrating the third semiconductor substrate 330 in the connection region CNR.

The second penetration plugs TP2 may be connected to conductive patterns GE0 to GEn of the second cell array structure CS2 through the third bonding pads BP3. In addition, the third sub-peripheral circuit layer SPC3 may include fourth peripheral bonding pads BPd in an insulating layer covering a back surface of the third semiconductor substrate 330.

In addition, as described above, each of the first and second cell array structures CS1 and CS2 may include common source lines CSL1 and CSL2, buried insulating patterns 110 and 120, stacks ST1 and ST2, vertical structures VS1 and VS2, bit lines BL1 and BL2, bit line contact plugs BPLG1 and BPLG2, cell contact plugs CPLG1 and CPLG2, input/output contact plugs IOPLG1 and IOPLG2, and bonding pads BP1 and BP2, respectively, as described above.

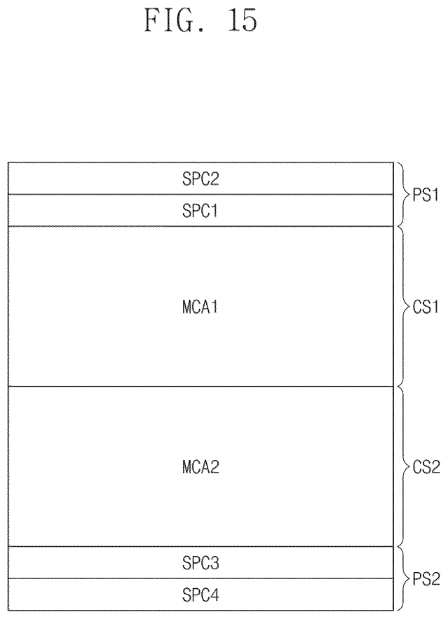

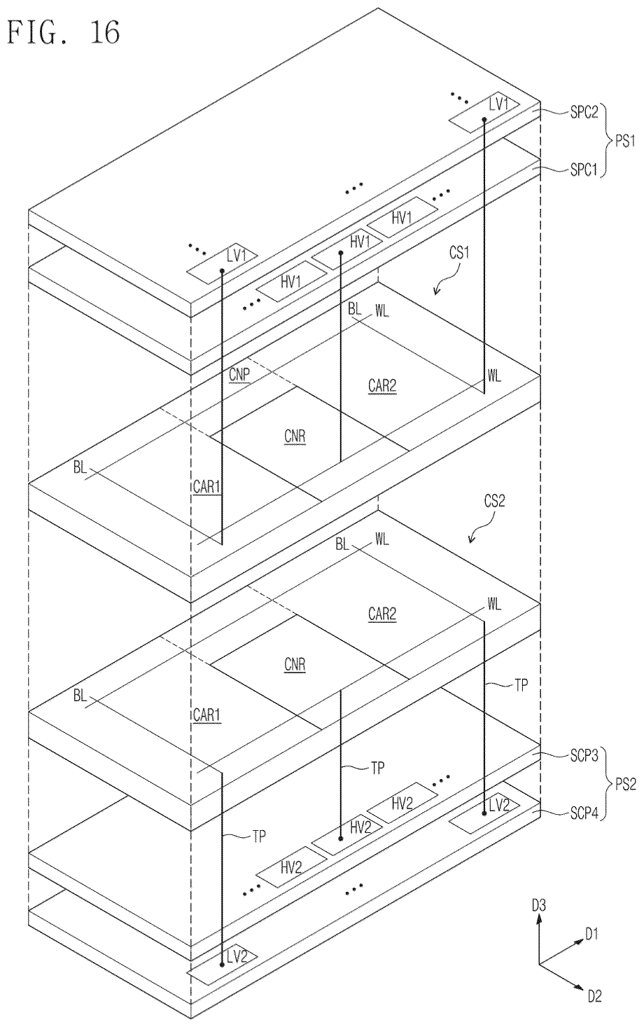

FIG. 15 is a cross-sectional view schematically illustrating a semiconductor device according to one or more embodiments. FIG. 16 is a perspective view schematically illustrating a semiconductor device according to one or more embodiments. FIG. 17 is a cross-sectional view schematically illustrating a semiconductor device according to one or more embodiments.

Referring to FIG. 15, a semiconductor device according to one or more embodiments may include a first peripheral circuit structure PS1 and a second peripheral circuit structure PS2 and a first cell array structure CS1 and a second cell array structure CS2 that vertically overlap the first peripheral circuit structure PS1 and a second peripheral circuit structure PS2.

As described above, each of the first and second cell array structures CS1 and CS2 may include a memory cell array MCA1 and MCA2 that includes word lines, bit lines, and three-dimensionally disposed memory cells.

In one or more embodiments, the first and second cell array structures CS1 and CS2 may be disposed between the first and second peripheral circuit structures PS1 and PS2.

For example, the first peripheral circuit structure PS1 may be disposed to be in contact with the first cell array structure CS1, and the second peripheral circuit structure PS2 may be disposed to be in contact with the second cell array structure CS2. The first peripheral circuit structure PS1 may include a first sub-peripheral circuit layer SPC1 including first high-voltage circuits HV1 and a second sub-peripheral circuit layer SPC2 including first low-voltage circuits LV1. The second peripheral circuit structure PS2 may include a third sub-peripheral circuit layer SPC3 including second high-voltage circuits HV2 and a fourth sub-peripheral circuit layer SPC4 including second low-voltage circuits LV2.

For example, referring to FIGS. 16 and 17, the first cell array structure CS1 may include a first common source line CSL1, a first stack ST1, first vertical structures VS1, first bit lines BL1, first conductive lines CL1, first bit line contact plugs BPLG1, first cell contact plugs CPLG1, and first input/output contact plugs IOPLG1. In addition, the first cell array structure CS1 may further include first bonding pads BP1 that are bonded to second bonding pads BP2 of the first peripheral circuit structure PS1.

The second cell array structure CS2 may include components having substantially the same characteristics as the first cell array structure CS1. For example, the second cell array structure CS2 may include a second common source line CSL2, a second stack ST2, second vertical structures VS2, second bit lines BL2, second conductive lines CL2, second bit line contact plugs BPLG2, second cell contact plugs CPLG2, and second input/output contact plugs IOPLG2. In addition, the second cell array structure CS2 may further include third bonding pads BP3 bonded to fourth bonding pads BP4 of the second peripheral circuit structure PS2.

The first and second cell array structures CS1 and CS2 may include the common features described above.

In one or more embodiments, the first cell array structure CS1 may include bonding pads in the first capping insulating layer 120 provided on and covering the first common source line CSL1, and the second cell array structure CS2 may include bonding pads in the second capping insulating layer 220 provided on and covering the second common source line CSL2.

The first capping insulating layer 120 may be directly bonded to the second capping insulating layer 220, and the bonding pads in the first and second capping insulating layers 120 and 220 may be directly bonded to each other. Accordingly, the first and second cell array structures CS1 and CS2 may be electrically connected to each other.

The first peripheral circuit structure PS1 and the first cell array structure CS1 may be directly bonded to each other.

In the first peripheral circuit structure PS1, the first sub-peripheral circuit layer SPC1 may include a first semiconductor substrate 310, a first row decoder circuit XDEC1, a first page buffer circuit PB1, a first penetration plug TP1, first peripheral bonding pads BPa, and second bonding pads BP2.

In the first sub-peripheral circuit layer SPC1, the first row decoder circuit XDEC1 and the first page buffer circuit PB1 may include first high-voltage transistors integrated and provided on the first semiconductor substrate 310, as described with reference to FIG. 5A. The first row decoder circuit XDEC1 may be electrically connected to the conductive patterns GE0 to GEn of the first cell array structure CS1 through the second bonding pads BP2. The first page buffer circuit PB1 may be electrically connected to the first bit lines BL1 of the first cell array structure CS1 through the second bonding pads BP2.

In the first peripheral circuit structure PS1, the second sub-peripheral circuit layer SPC2 may include a second semiconductor substrate 320, a second page buffer circuit PB2, and second peripheral bonding pads BPb.

The second page buffer circuit PB2 may be integrated and provided on an upper surface of the second semiconductor substrate 320, and may include low-voltage transistors integrated and provided on the second semiconductor substrate 320, as described with reference to FIG. 5B. The second page buffer circuit PB2 may be electrically connected to the first bit lines BL1 of the first cell array structure CS1 through the first penetration plugs TP1 penetrating the first semiconductor substrate 310.

The second peripheral circuit structure PS1 and the first cell array structure CS1 may be directly bonded to each other.

In the second peripheral circuit structure PS2, the third sub-peripheral circuit layer SPC3 may include a third semiconductor substrate 330, a second row decoder circuit XDEC2, a third page buffer circuit PB3, a second penetration plug TP2, third peripheral bonding pads BPc, and fourth bonding pads BP4.

In the third sub-peripheral circuit layer SPC3, the second row decoder circuit XDEC2 and the third page buffer circuit PB3 may include second high-voltage transistors integrated on the first semiconductor substrate 310, as described with reference to FIG. 5A. The second row decoder circuit XDEC2 may be electrically connected to the conductive patterns GE0 to GEn of the second cell array structure CS2 through the fourth bonding pads BP4. The third page buffer circuit PB3 may be electrically connected to the second bit lines BL2 of the second cell array structure CS2 through the fourth bonding pads BP4.

In the second peripheral circuit structure PS2, the fourth sub-peripheral circuit layer SPC4 may include a fourth semiconductor substrate 340, a fourth page buffer circuit PB4, and fourth peripheral bonding pads BPd.

The fourth page buffer circuit PB4 may be integrated and provided on an upper surface of the fourth semiconductor substrate 340 and may include low-voltage transistors integrated on the fourth semiconductor substrate 340, as described with reference to FIG. 5B. The fourth page buffer circuit PB4 may be electrically connected to the second bit lines BL2 of the second cell array structure CS2 through the second penetration plugs TP2 penetrating the third semiconductor substrate 330.

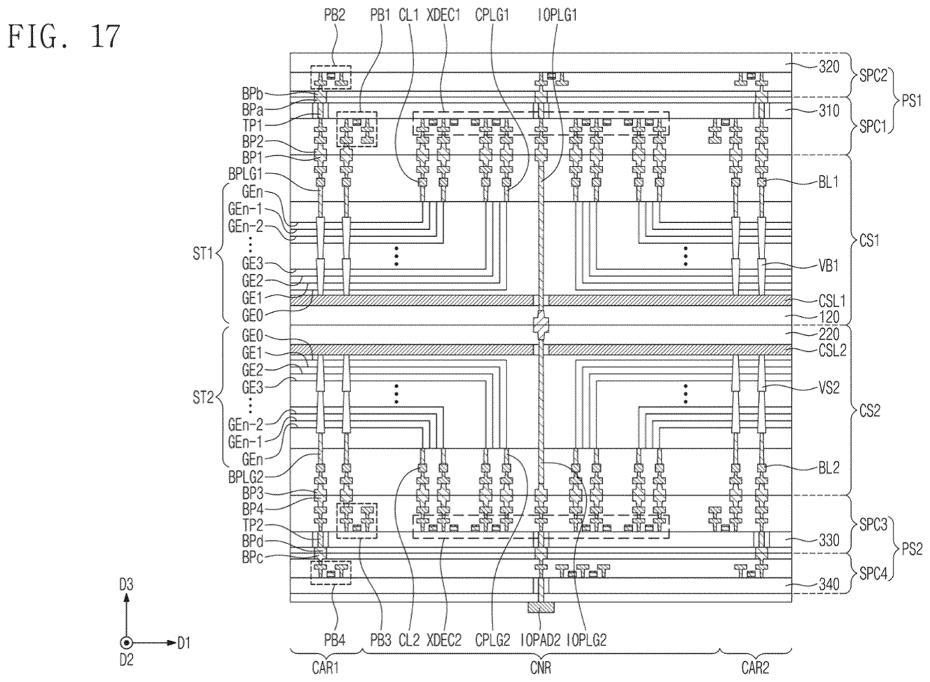

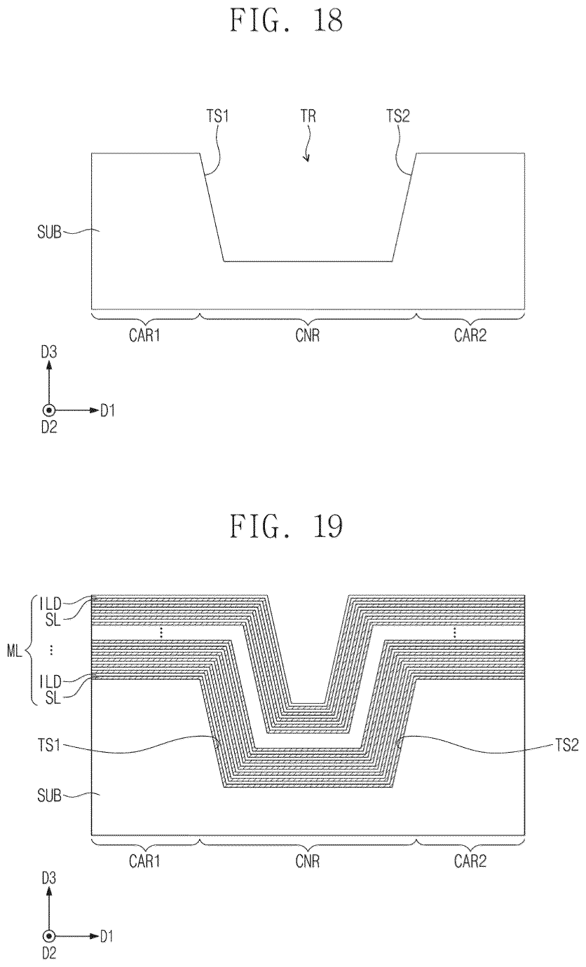

FIGS. 18 to 24 are cross-sectional views illustrating a method of manufacturing a semiconductor device according to one or more embodiments.

Referring to FIG. 18, a substrate SUB may be partially patterned to form a trench TR in a connection region CNR. The forming of the trench TR may include forming a mask pattern on an upper surface of the substrate SUB and then etching a portion of the substrate SUB.

The substrate SUB may be, for example, a silicon substrate, a silicon-germanium substrate, a germanium substrate, or a single-crystal epitaxial layer grown on a monocrystalline silicon substrate. The substrate SUB may include a first cell array region CAR1, a second cell array region CAR2, and a connection region CNR. The upper surface of the substrate SUB may be parallel to a first direction D1 and a second direction D2 that intersect each other.

The trench TR may have a sidewall inclined with respect to the upper surface of the substrate SUB. The trench TR may have first and second sidewalls TS1 and TS2 inclined with respect to the upper surface of the substrate SUB. The first and second sidewalls TS1 and TS2 may face each other in the first direction D1, and the first and second sidewalls may have an inclination of about 90 degrees to 130 degrees with respect to the upper surface of the substrate SUB.

Referring to FIG. 19, a mold structure ML may be formed by alternately and repeatedly stacking insulating layers ILD and sacrificial layers SL on a substrate SUB on which the trench TR is formed. The mold structure ML may extend continuously from the first cell array region CAR1 to the second cell array region CAR2.

The mold structure ML may be deposited using, for example, thermal chemical vapor deposition (thermal CVD), plasma enhanced CVD, physical chemical vapor deposition (physical CVD), or atomic layer deposition (ALD) technology. Accordingly, the mold structure ML may have a uniform thickness on the first and second cell array regions CAR1 and CAR2 and the connection region CNR, and may define a recess region in the trench TR of the connection region CNR.

In the mold structure ML, the sacrificial layers SL may have substantially the same thickness, and some of the insulating layers ILD may have different thicknesses. In the mold structure ML, the sacrificial layers SL may be formed of a material having etch selectivity with respect to the insulating layers ILD. For example, the sacrificial layers SL may be formed of an insulating material different from that of the insulating layers ILD. For example, the sacrificial layers SL may be formed of a silicon nitride layer, and the insulating layers ILD may be formed of a silicon oxide layer.

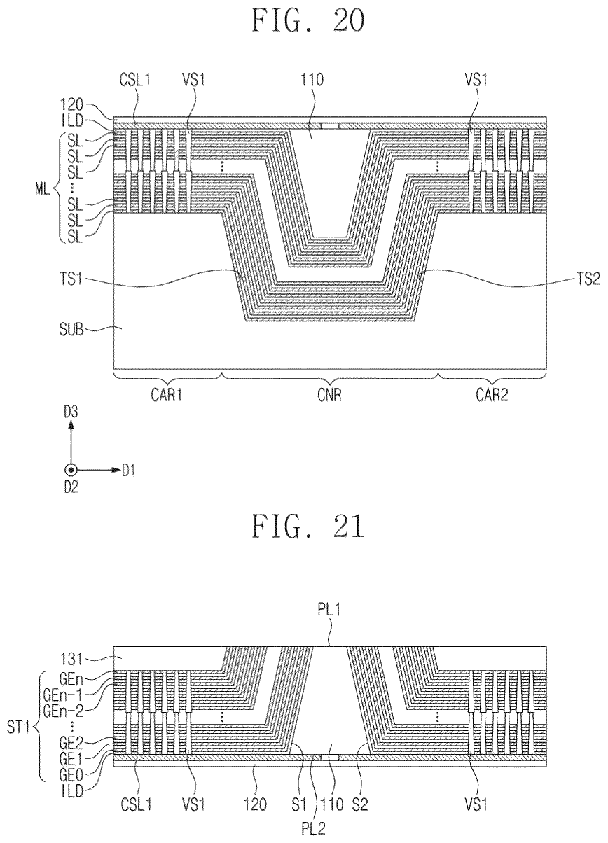

Referring to FIG. 20, after the mold structure ML is formed, a buried insulating pattern 110 may be formed that fills the trench in which the mold structure ML is formed.

The forming of the buried insulating pattern 110 may include depositing a thick buried insulating layer on the mold structure ML, and then performing a planarization process on the buried insulating layer so that an upper surface of the mold structure ML is exposed. Accordingly, the upper surface of the buried insulating pattern 110 may be substantially coplanar with an upper surface of the mold structure ML in the first and second cell array regions CAR1 and CAR2. Hereinafter, substantially coplanar may indicate that a planarization process may be performed. The planarization process may be performed through, for example, a chemical mechanical polishing (CMP) process or an etch back process.

After forming the buried insulating pattern 110, first vertical structures VS1 penetrating the mold structure ML in the first and second cell array regions CAR1 and CAR2 may be formed. Each of the first vertical structures VS1 may have a width that decreases as the first vertical structures VS1 approach the upper surface of the substrate SUB.

The forming of the first vertical structures VS1 may include forming vertical channel holes that penetrate the mold structure ML to expose the substrate SUB, sequentially depositing a data storage layer and a vertical channel layer in the vertical channel holes, and etching and planarizing the data storage layer and the vertical channel layer.

Subsequently, first source conductive pads may be formed on upper ends of the first vertical structures VS1. The first source conductive pads may be impurity regions doped with impurities or may be formed of a conductive material.

A first common source line CSL1 may be formed on the mold structure ML. The first common source line CSL1 may be formed by depositing a conductive layer on the mold structure ML and then patterning the conductive layer. The first common source line CSL1 may be in direct contact with an upper surfaces of the first vertical structures VS1, i.e., the first source conductive pads. The first common source line CSL1 may be continuously extended from the first cell array region CAR1 to the second cell array region CAR2.

An insulating pattern penetrating the first common source line CSL1 may be formed on the buried insulating pattern 110 in the connection region CNR, and a first capping insulating layer 120 may be formed on the first common source line CSL1.

Subsequently, referring to FIG. 21, a carrier substrate may be attached to the first capping insulating layer 120 using an adhesive layer. The carrier substrate may be, for example, a glass substrate or a semiconductor substrate. The adhesive layer may be, for example, a polymer tape including an insulating material.

After attaching the carrier substrate, the first stack ST1 may be upside down. For example, the substrate SUB may be positioned at the top, and the trench and the mold structure ML may be disposed in an upside-down form. In addition, the buried insulating pattern 110 may have a trapezoidal cross-section.

Thereafter, a portion of the substrate SUB and the mold structure ML may be removed to expose the buried insulating pattern 110. The buried insulating pattern 110 may have a first side surface S1 and a second side surface S2 that are in contact with the inclined surfaces of the mold structure ML in the trench TR. The mold structure ML may have a first plane PL1 and a second plane PL2 that are parallel to each other. A width in the first plane PL1 may be less than a width in the second plane PL2.

Removing a portion of the substrate SUB and the mold structure ML may include a grinding process, a planarization process, a dry etching process, and a wet etching process.

After exposing the buried insulating pattern 110, a process of replacing a portion of the substrate SUB remaining in the first and second cell array regions CAR1 and CAR2 with a first insulating layer 131 may be performed. Accordingly, the lowermost interlayer insulating layer ILD of the mold structure ML and lower surfaces of the first vertical structures VS1 may be in contact with the first insulating layer 131. Here, the lowermost layer may be a layer deposited first in the process of forming the mold structure ML. An upper surface of the first insulating layer 131 may be substantially coplanar with upper surfaces of the pad portions of the first stack ST1.

Then, a first stack ST1 may be formed by replacing the sacrificial layers SL of the mold structure ML with conductive patterns GE0 to GEn.

The forming of the first stack ST1 may include forming trenches penetrating the mold structure ML, replacing the sacrificial layers SL exposed in the trenches with conductive materials to form conductive patterns GE0 to GEn between interlayer insulating layers ILD, and filling the trenches with an insulating material to form separation structures. Each of the conductive patterns GE0 to GEn formed as above described may have a horizontal portion in the first and second cell array regions CAR1 and CAR2 and a pad portion parallel to the first and second side surfaces S1 and S2 of the buried insulating pattern 110 in the connection region CNR. For example, each of the conductive patterns GE0 to GEn may have an L-shaped cross section.

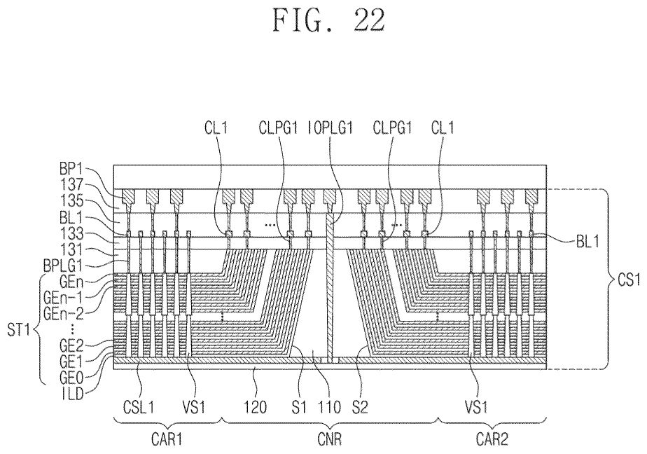

Referring to FIG. 22, a second insulating layer 133 may be formed on the first insulating layer 131 and the first stack ST1.

After forming the second insulating layer 133, cell contact plugs CPLG connected to the conductive patterns GE0 to GEn of the first stack ST1 in the connection region CNR may be formed, and bit line contact plugs BPLG1 connected to the first vertical structures VS1 in the first and second cell array regions CAR1 and CAR2 may be formed.

Bit lines BL1 may be formed on the second insulating layer 133 in the first and second cell array regions CAR1 and CAR2, and conductive lines CL1 may be formed on the second insulating layer 133 in the connection region CNR. The bit lines BL1 may be connected to the bit line contact plugs BPLG1, and the conductive lines CL1 may be connected to cell contact plugs CPLG1.

Subsequently, a third insulating layer 135 may be formed on the second insulating layer 133, and then, in the connection region CNR, first input/output contact plugs IOPLG1 penetrating the third insulating layer 135, the second insulating layer 133, the buried insulating pattern 110, and the first common source line CSL1 may be formed.

First bonding pads BP1 may be formed in a fourth insulating layer 137 (i.e., the uppermost insulating layer) on the third insulating layer 135. The first bonding pads BP1 may be electrically connected to the bit lines BL1 and the conductive patterns GE0 to GEn of the first stack ST1 through contact plugs and wirings. The first bonding pads BP1 may be formed using a damascene process. Upper surfaces of the first bonding pads BP1 may be substantially coplanar with an upper surface of the third insulating layer 135.

The first bonding pads BP1 may be formed to form a first cell array structure CS1.

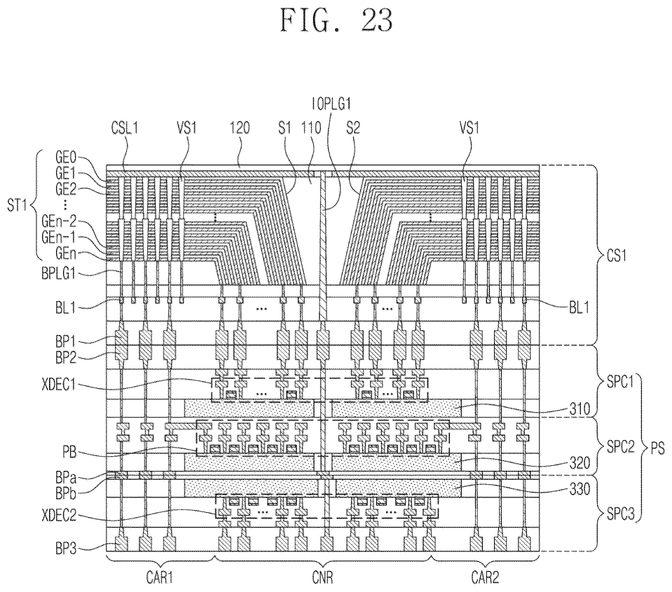

Referring to FIG. 23, after forming the first cell array structure CS1, the peripheral circuit structure PS including the second bonding pads BP2 may be bonded to each other. For example, the first bonding pads BP1 of the first cell array structure CS1 and the second bonding pads BP2 of the peripheral circuit structure PS may be bonded to each other. Accordingly, the first bonding pads BP1 and the second bonding pads BP2 may be bonded to each other, and the uppermost insulating layer of the first cell array structure CS1 and the uppermost insulating layer of the peripheral circuit structure PS may be bonded to each other.

In one or more embodiments, providing a peripheral circuit structure may include forming a first sub-peripheral circuit layer SPC1 including first high-voltage circuits, for example, a first row decoder circuit XDEC1, formed on a first semiconductor substrate 310, forming a second sub-peripheral circuit layer SPC2 including low-voltage circuits, for example, a page buffer circuit PB, formed on a second semiconductor substrate 320, forming a third sub-peripheral circuit layer SPC3 including second high-voltage circuits, for example, a second row decoder circuit XDEC2, formed on a third semiconductor substrate 330, connecting and bonding the first sub-peripheral circuit layer SPC1 and the second sub-peripheral circuit layer SPC2 to each other, and connecting and bonding the second sub-peripheral circuit layer SPC2 and the third sub-peripheral circuit layer SPC3 to each other.

Here, forming the first sub-peripheral circuit layer SPC1 may include forming the second bonding pads BP2, and forming the third sub-peripheral circuit layer SPC3 may include forming third bonding pads BP3. In addition, the first sub-peripheral circuit layer SPC1 and the second sub-peripheral circuit layer SPC2 may be electrically connected to each other through penetration vias penetrating the first semiconductor substrate 310, or may be manufactured separately on different wafers and then connected to each other by a bonding method. Similarly, the third sub-peripheral circuit layer SPC3 and the second sub-peripheral circuit layer SPC2 may be electrically connected to each other through penetration vias penetrating the third semiconductor substrate 330, or may be manufactured separately on different wafers and then connected to each other by a bonding method.

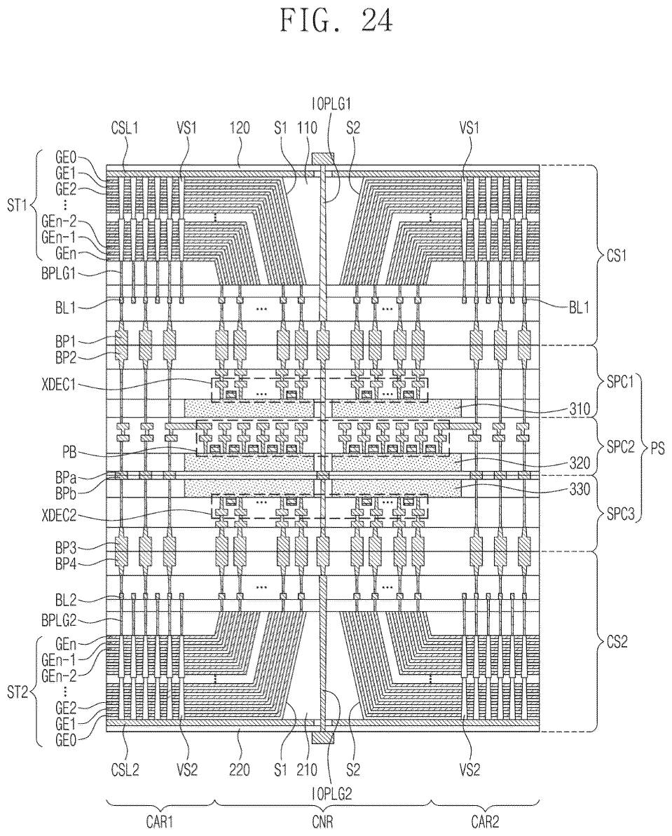

Referring to FIG. 24, a second cell array structure CS2 may be formed in the same manner as described above with reference to FIGS. 18 to 22, and the second cell array structure CS2 may have fourth bonding pads BP4 formed in the uppermost insulating layer.

The fourth bonding pads BP4 of the second cell array structure CS2 may be bonded to third bonding pads BP3 of the peripheral circuit structure PS.

Thereafter, first input/output pads IOPAD1 connected to first input/output contact plugs IOPLG1 may be formed on the uppermost insulating layer of the first cell array structure CS1, and second input/output pads IOPAD2 connected to second input/output contact plugs IOPLG2 may be formed on the uppermost insulating layer of the second cell array structure CS2.

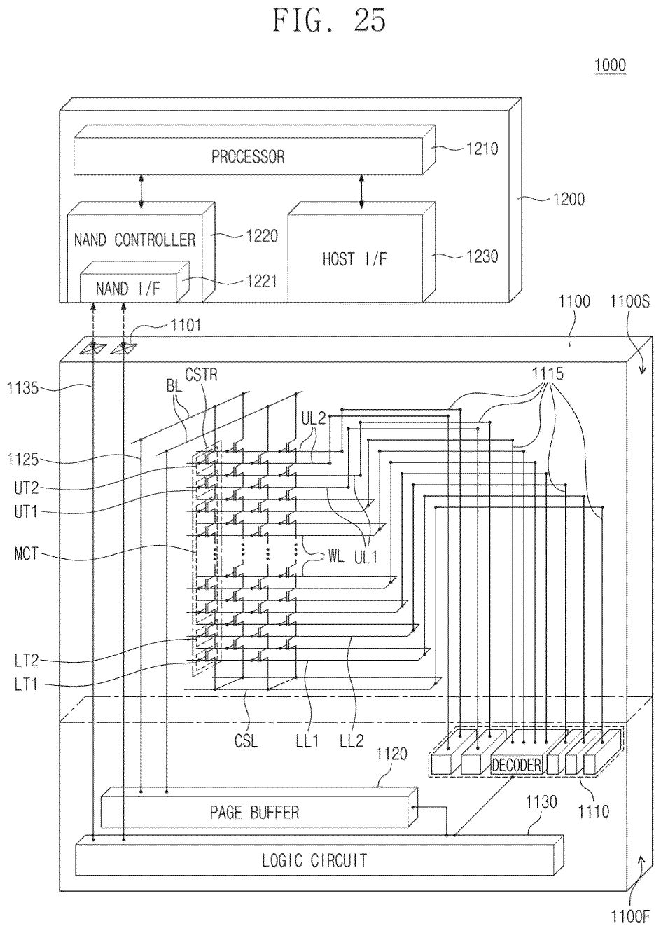

FIG. 25 is a schematic diagram of an electronic system including a semiconductor device according to one or more embodiments.

Referring to FIG. 25, an electronic system 1000 according to one or more embodiments may include may include a semiconductor device 1100 and a controller 1200 electrically connected to the semiconductor device 1100. The electronic system 1000 may be implemented as a storage device including the semiconductor device 1100, or an electronic device including a storage device. For example, the electronic system 1000 may be implemented by a solid state drive device (SSD), a universal serial bus (USB), a computing system, a medical device, or a communication device, which may include one or more semiconductor devices 1100.

The semiconductor device 1100 may be a nonvolatile memory device, for example, a NAND flash memory device. The semiconductor device 1100 may include a first structure 1100F and a second structure 1100S on the first structure 1100F. In one or more embodiments, the first structure 1100F may be disposed next to the second structure 1100S.

The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to a common source line CSL, upper transistors UT1 and UT2 adjacent to a bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed depending on the embodiments.

In one or more embodiments, the upper transistors UT1 and UT2 may include string selection transistors, and the lower transistors LT1 and LT2 may include ground selection transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In one or more embodiments, the lower transistors LT1 and LT2 may include a serially connected lower erase control transistor LT1 and a ground selection transistor LT2. The upper transistors UT1 and UT2 may include a serially connected string selection transistor UT1 and an upper erase control transistor UT2. At least one of the lower erase control transistor LT1 and the upper erase control transistor UT1 may be used for an erase operation that erases data stored in the memory cell transistors MCT by utilizing a gate induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection wirings 1115 extending from the first structure 1100F to the second structure 1100S. The bit lines BL may be electrically connected to the page buffer 1120 through second connection wirings 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with a controller 1200 through an input/output pad 1101 that is electrically connected to the logic circuit 1130. The input/output pad 1101 may be electrically connected to the logic circuit 1130 through an input/output connection wiring 1135 that extends from the first structure 1100F to the second structure 1100S.

The first structure 1100F may include a voltage generator 3 (refer to FIG. 1). The voltage generator may generate a program voltage, a read voltage, a pass voltage, a verification voltage, etc. that are necessary for the operation of the memory cell strings CSTR. Here, the program voltage may be a relatively high voltage (e.g., 20 V to 40 V) compared to the read voltage, the pass voltage, and the verification voltage.

In one or more embodiments, the first structure 1100F may include high-voltage transistors and low-voltage transistors. The decoder circuit 1110 may include pass transistors connected to the word lines WL of the memory cell strings CSTR. The pass transistors may include high-voltage transistors that may withstand a high voltage, such as the program voltage applied to the word lines WL during a program operation. The page buffer 1120 may also include high-voltage transistors that may withstand a high voltage.

The controller 1200 may include a processor 1210, a NAND controller 1220, and a host interface 1230. According to embodiments, the electronic system 1000 may include a plurality of semiconductor devices 1100, and in this case, the controller 1200 may control the plurality of semiconductor devices 1100. The processor 1210 may control the overall operation of the electronic system 1000 including the controller 1200.

The processor 1210 may operate according to a certain firmware and may control the NAND controller 1220 to access the semiconductor device 1100. The NAND controller 1220 may include a NAND interface 1221 that processes communication with the semiconductor device 1100. Through the NAND interface 1221, a control command for controlling the semiconductor device 1100, data to be written to the memory cell transistors MCT of the semiconductor device 1100, data to be read from the memory cell transistors MCT of the semiconductor device 1100 may be transmitted. The host interface 1230 may provide a communication function between the electronic system 1000 and an external host. When receiving a control command from an external host through the host interface 1230, the processor 1210 may control the semiconductor device 1100 in response to the control command.

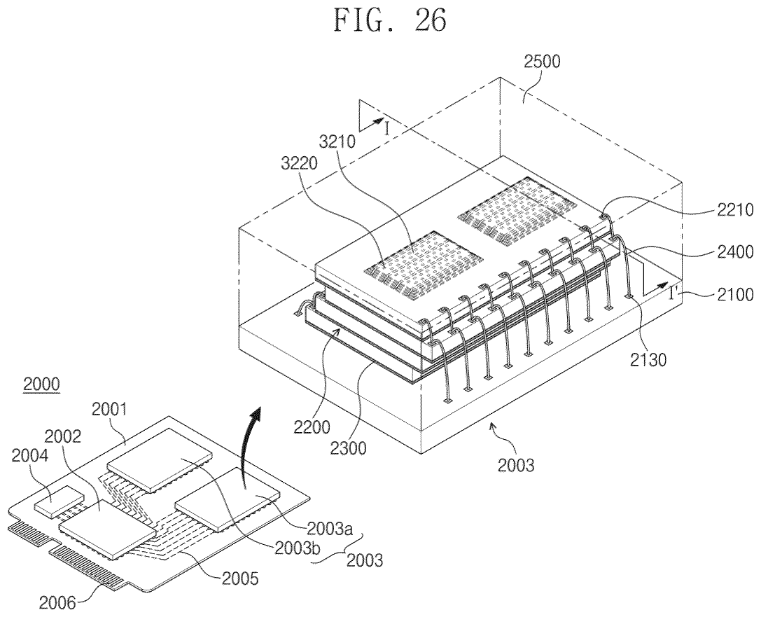

FIG. 26 is a perspective view schematically illustrating an electronic system including a semiconductor device according to one or more embodiments.

Referring to FIG. 26, an electronic system 2000 according to one or more embodiments may include a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 through wiring patterns 2005 provided in the main board 2001.

The main board 2001 may include a connector 2006 including a plurality of pins which are provided to have connection with an external host. The number and arrangement of the plurality of pins on the connector 2006 may be changed based on a communication interface between the electronic system 2000 and the external host. The electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS). For example, the electronic system 2000 may operate with power supplied through the connector 2006 from the external host. The electronic system 2000 may further include a power management integrated circuit (PMIC) that distributes the power supplied from the external host to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a cache memory, and may provide a space for temporary data storage in a control operation of the semiconductor package 2003. When the DRAM 2004 is included in the electronic system 2000, the controller 2002 may include not only a NAND controller for control of the semiconductor package 2003, but a DRAM controller for control of the DRAM 2004.

The semiconductor package 2003 may include a first semiconductor package 2003a and a second semiconductor package 2003b that are spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesive layers 2300 on lower surfaces of the semiconductor chips 2200, connection structures 2400 that electrically connect the semiconductor chips 2200 to the package substrate 2100, and a molding layer 2500 that lies on the package substrate 2100 and covers or overlaps the semiconductor chips 2200 and the connection structures 2400.

The package substrate 2100 may be a printed circuit board including upper pads 2130. Each semiconductor chip 2200 may include an input/output pad 2210. The input/output pad 2210 may correspond to the input/output pad 1101 of FIG. 25. Each of the semiconductor chips 2200 may include stacked structures 3210 and vertical structures 3220. Each of the semiconductor chips 2200 may include a semiconductor device according to embodiments of the inventive concept described below.

In some embodiments, the connection structures 2400 may be, for example, bonding wires that electrically connect the input/output pads 2210 to the package upper pads 2130. Therefore, on each of the first and second semiconductor packages 2003a and 2003b, the semiconductor chips 2200 may be electrically connected to each other in a wire bonding manner, and may be electrically connected to the package upper pads 2130 of the package substrate 2100. In embodiments, on each of the first and second semiconductor packages 2003a and 2003b, the semiconductor chips 2200 may be electrically connected to each other using through-silicon vias instead of the connection structures 2400 or the bonding wires.

In some embodiments, the controller 2002 and the semiconductor chips 2200 may be included in a single package. The controller 2002 and the semiconductor chips 2200 may be mounted on a separate interposer substrate other than the main board 2001, and may be connected to each other through wiring lines provided in the interposer substrate.

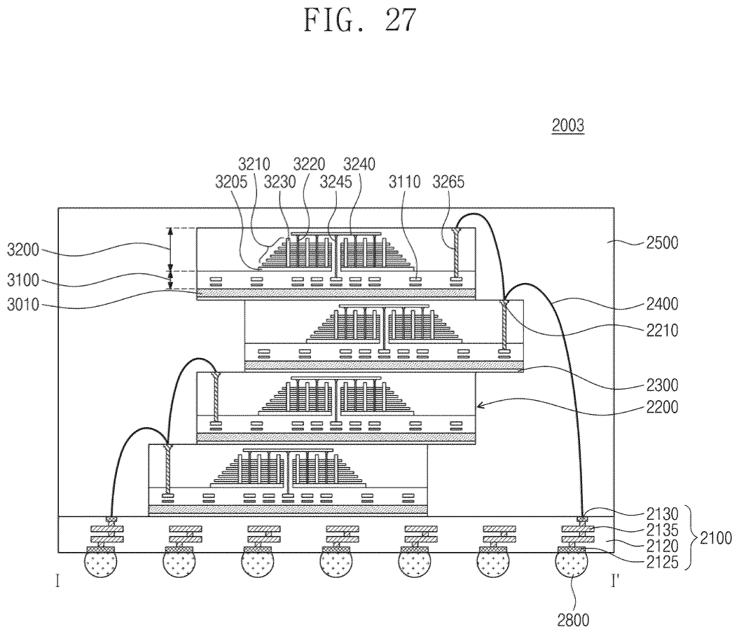

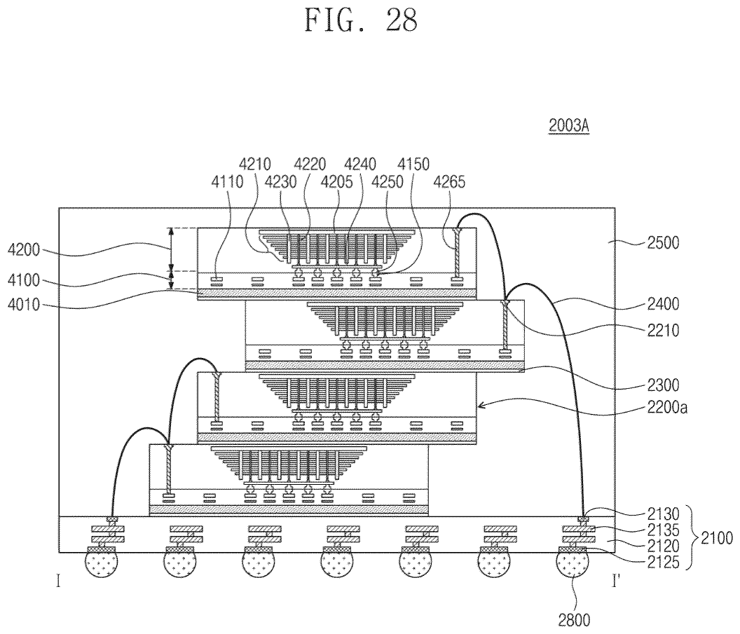

FIGS. 27 and 28 are cross-sectional views schematically illustrating semiconductor packages according to one or more embodiments, conceptually illustrating a section taken along line I-I′ of the semiconductor package of FIG. 26.

Referring to FIG. 27, in the semiconductor package 2003, the package substrate 2100 may be a printed circuit board. The package substrate 2100 may include a package substrate body 2120, upper pads 2130 (refer to FIG. 26) disposed on an upper surface of the package substrate body 2120, lower pads 2125 disposed on a lower surface of the package substrate body 2120 or exposed by the lower surface, and internal wirings 2135 electrically connecting the upper pads 2130 and the lower pads 2125 in the package substrate body 2120. The upper pads 2130 may be electrically connected to a connection structures 2400. The lower pads 2125 may be connected to the wiring patterns 2005 of the main board 2001 of the electronic system 2000 as shown in FIG. 26 through conductive connection portions 2800.

Each of semiconductor chips 2200 may include a semiconductor substrate 3010 and a first structure 3100 and a second structure 3200 sequentially stacked on the semiconductor substrate 3010. The first structure 3100 may include a peripheral circuit region including peripheral wirings 3110. The second structure 3200 may include a source structure 3205, a stacked structure 3210 on the source structure 3205, vertical structures 3220 penetrating the stacked structure 3210, separation structures, bit lines 3240 electrically connected to the vertical structures 3220, and cell contact plugs electrically connected to word lines WL (refer to FIG. 25) of the stacked structure 3210. Each of the first structure 3100/second structure 3200/semiconductor chips 2200 may further include separation structures 3230 described later.

Each of the semiconductor chips 2200 may include a penetration line 3245 that is electrically connected to the peripheral wirings 3110 of the first structure 3100 and extends into the second structure 3200. The penetration line 3245 may be disposed on the outside of the stacked structure 3210 and may be further disposed to penetrate the stacked structure 3210. Each of the semiconductor chips 2200 may further include an input/output pad 2210 (refer to FIG. 26) that is electrically connected to the peripheral wirings 3110 of the first structure 3100. Each of the semiconductor chips 2200 may further include an input/output interconnection wiring 3265 electrically connected to the peripheral wirings 3110 of the first structure 3100 and extended in the second structure 3200, and an input/output pad 2210 electrically connected to the input/output interconnection wiring 3265. For example, the input/output interconnection wiring 3265 may extend in a vertical direction from the first structure 3100 through the second structure 3200 to contact the input/output pad 2210.

Referring to FIG. 28, in a semiconductor package 2003A, each of the semiconductor chips 2200 may include a semiconductor substrate 4010, a first structure 4100 on the semiconductor substrate 4010, and a second structure 4200 bonded to the first structure 4100 in a wafer bonding manner on the first structure 4100.

The first structure 4100 may include a peripheral circuit region including peripheral wiring 4110 and first bonding structures 4150. The second structure 4200 may include a source structure 4205, a stacked structure 4210 between the source structure 4205 and the first structure 4100, vertical structures 4220 penetrating the stacked structure 4210, a separation structure 4230, and second junction structures 4250 electrically connected to the word lines (WL of FIG. 25) of the vertical structures 4220 and the stacked structure 4210, respectively. For example, the second bonding structures 4250 may be electrically connected to the vertical structures 4220 and the word lines WL (refer to FIG. 25), respectively, through bit lines 4240 electrically connected to the vertical structures 4220 and cell contact plugs electrically connected to the word lines WL (refer to FIG. 25). The first bonding structures 4150 of the first structure 4100 and the second bonding structures 4250 of the second structure 4200 may be bonded while being in contact with each other. The bonded portions of the first bonding structures 4150 and the second bonding structures 4250 may be formed of, for example, copper (Cu).

Each of the first structure 4100/the second structure 4200/the semiconductor chips 2200 may further include a source structure according to the one or more embodiments described below. Each of the semiconductor chips 2200 may further include an input/output pad 2210 electrically connected to the peripheral wirings 4110 of the first structure 4100 and an input/output interconnection wiring 4265 under the input/output pad 2210. The input/output interconnection wiring 4265 may be electrically connected to the peripheral wirings 4110 of the first structure 4100.

The semiconductor chips 2200 of FIG. 27 or the semiconductor chips 2200a of FIG. 28 may be electrically connected to each other by connection structures 2400 in the form of bonding wires. However, in embodiments, the semiconductor chips 2200 in one semiconductor package including the semiconductor chips 2200 of FIG. 27 or the semiconductor chips 2200a of FIG. 28 may be electrically connected to each other by connection structures including through-silicon vias (TSV).

The first structure 3100 of FIG. 27 and the first structure 4100 of FIG. 28 may correspond to the peripheral circuit structures in the embodiments described above, and the second structure 3200 of FIG. 27 and the second structure 4200 of FIG. 28 may correspond to the cell array structures in the one or more embodiments described above.

According to one or more embodiments, the pad portions of the conductive patterns may be positioned at substantially the same level, and thus the cell contact plugs connected to the conductive patterns may have the same length.

The pad portions of each conductive pattern may be disposed to be provided on and surround the three side surfaces of the buried insulating pattern, and thus the cell contact plug may be connected to the pad portion to be adjacent to one of the three side surfaces of the buried insulating pattern. For example, the spacing between the cell contact plugs may be increased, thereby improving the process margin.

The input/output contact plugs may be disposed to penetrate the buried insulating pattern disposed in the connection region between the cell array regions, thereby reducing the area of the semiconductor device.

The peripheral circuit structure vertically overlapping the cell array structure may include the peripheral circuits that are divided and disposed on the plurality of substrates, thereby reducing the area of the peripheral circuit structure.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor device comprising:
a peripheral circuit structure comprising peripheral circuits; and
a cell array structure overlapping the peripheral circuit structure and comprising a first cell array region, a second cell array region, and a connection region between the first cell array region and the second cell array region in a first direction,
wherein the cell array structure comprises:
a buried insulating pattern in the connection region, the buried insulating pattern comprising a first side surface and a second side surface facing each other in the first direction and a third side surface connecting the first side surface and the second side surface;
a stack in the first cell array region, the second cell array region, and the connection region, the stack comprising conductive patterns stacked in a vertical direction, each conductive pattern of the conductive patterns comprising a horizontal portion parallel to the first direction and a pad portion inclined with respect to the horizontal portion; and
cell contact plugs connected to the pad portion of each conductive pattern of the conductive patterns, respectively,
wherein the pad portion of each conductive pattern of the conductive patterns is on the first side surface of the buried insulating pattern, the second side surface of the buried insulating pattern, and the third side surface of the buried insulating pattern,
wherein the pad portion of each conductive pattern of the conductive patterns are spaced apart from each other by a first space in the first direction, and
wherein the cell contact plugs are spaced apart from each other by a second space greater than the first space in the first direction.

2. The semiconductor device of claim 1, wherein the pad portion of each conductive pattern of the conductive patterns comprise a first portion adjacent to the first side surface, a second portion adjacent to the second side surface, and a third portion adjacent to the third side surface, and
wherein each cell contact plug of the cell contact plugs are connected to one of the first portion of the pad portion, the second portion of the pad portion, and the third portion of the pad portion.

3. The semiconductor device of claim 1, wherein the second space is at least three times greater than the first space.

4. The semiconductor device of claim 1, wherein the stack has a first width in a second direction intersecting the first direction, and
wherein one pad portion of the pad portions of the conductive patterns has a second width in the second direction, and the second width is less than the first width.

5. The semiconductor device of claim 1, wherein a length of each cell contact plug of the cell contact plugs is the same in the vertical direction.

6. The semiconductor device of claim 1, wherein the buried insulating pattern comprises a first plane and a second plane vertically opposite to the first plane, the first plane being closer to the peripheral circuit structure than the second plane, and
wherein upper surfaces of the pad portions of the conductive patterns are coplanar with the first plane of the buried insulating pattern.

7. The semiconductor device of claim 1, wherein the first side surface of the buried insulating pattern, the second side surface of the buried insulating pattern, and the third side surface of the buried insulating pattern have an inclination of 90 degrees to 130 degrees with respect to the horizontal portion of each conductive pattern.

8. The semiconductor device of claim 1, wherein the buried insulating pattern has a first plane and a second plane opposite to the first plane in the vertical direction, the first plane being closer to the peripheral circuit structure than the second plane, and
wherein, in the first direction, a width in the first plane is less than a width in the second plane.

9. The semiconductor device of claim 1, wherein the cell array structure further comprises input/output contact plugs penetrating the buried insulating pattern in the connection region.

10. The semiconductor device of claim 1, wherein the cell array structure further comprises vertical structures penetrating the horizontal portion of each conductive pattern of the conductive patterns in the first cell array region and the second cell array region.

11. The semiconductor device of claim 10, wherein each vertical structure of the vertical structures has a lower surface and an upper surface opposite to the lower surface in the vertical direction, the lower surface being closer to the peripheral circuit structure than the upper surface, and
wherein a width at the lower surface of each vertical structure of the vertical structures is less than a width at the upper surface of each vertical structure of the vertical structures in the first direction.

12. The semiconductor device of claim 10, wherein the cell array structure further comprises first bonding pads connected to the cell contact plugs and the vertical structures,
wherein the peripheral circuit structure further comprises second bonding pads connected to the peripheral circuits, and
wherein the second bonding pads are directly bonded to the first bonding pads.

13. The semiconductor device of claim 12, wherein the peripheral circuit structure comprises:
a first sub-peripheral circuit layer comprising first high-voltage circuits and second bonding pads connected to the first high-voltage circuits, the second bonding pads being directly bonded to the first bonding pads of the first cell array region; and
a second sub-peripheral circuit layer comprising low-voltage circuits connected to the second bonding pads, and
wherein the second sub-peripheral circuit layer overlaps the first sub-peripheral circuit layer in the vertical direction.

14. A semiconductor device comprising:
a first cell array structure and a second cell array structure comprising a first cell array region, a second cell array region, and a connection region between the first cell array region and the second cell array region in a first direction; and
a peripheral circuit structure between the first cell array structure and the second cell array structure in a second direction perpendicular to the first direction,
wherein each of the first cell array structure and the second cell array structure comprises:
a buried insulating pattern in the connection region, the buried insulating pattern comprising a first side surface and a second side surface facing each other in the first direction and a third side surface connecting the first side surface and the second side surface;
a stack comprising conductive patterns stacked in the first cell array region, the second cell array region, and the connection region in the second direction, each conductive pattern of the conductive patterns comprising a horizontal portion parallel to the first direction and a pad portion inclined with respect to the horizontal portion;
vertical structures penetrating the stack;
bit lines crossing the stack and connected to the vertical structures;
cell contact plugs respectively connected to the pad portions of the conductive patterns; and
input/output contact plugs penetrating the buried insulating pattern,
wherein the peripheral circuit structure comprises:
a first sub-peripheral circuit layer comprising first high-voltage circuits on a first semiconductor substrate and second bonding pads connected to the first high-voltage circuits and directly bonded to first bonding pads of the first cell array structure;
a second sub-peripheral circuit layer comprising second high-voltage circuits on a second semiconductor substrate and fourth bonding pads connected to the second high-voltage circuits and directly bonded to third bonding pads of the second cell array structure; and
a third sub-peripheral circuit layer comprising low-voltage circuits on a third semiconductor substrate between the first sub-peripheral circuit layer and the second sub-peripheral circuit layer, and
wherein the cell contact plugs are spaced apart from each other by a second space and the pad portions are spaced apart from each other by a first space that is less than the second space.

15. The semiconductor device of claim 14, wherein the horizontal portion of each conductive pattern of the conductive patterns extend continuously from the first cell array region to the second cell array region through the connection region.

16. The semiconductor device of claim 14, wherein the pad portion of each conductive pattern comprises a first portion adjacent to the first side surface, a second portion and the second side surface, and a third portion adjacent to the third side surface, and
wherein each cell contact plug of the cell contact plugs is connected to one of the first portion of the pad portion, the second portion of the pad portion, and the third portion of the pad portion.

17. The semiconductor device of claim 14, wherein the buried insulating pattern comprises a first plane and a second plane opposite to the first plane in a vertical direction, the first plane being closer to the peripheral circuit structure than the second plane, and
wherein upper surfaces of the pad portions of the conductive patterns are substantially coplanar with the first plane of the buried insulating pattern.

18. The semiconductor device of claim 17, wherein, in the first direction, a width of the buried insulating pattern in the first plane is less than a width of the buried insulating pattern in the second plane.

19. The semiconductor device of claim 14, wherein, in the third sub-peripheral circuit layer, the third semiconductor substrate has a first surface and a second surface facing each other, and
wherein the low-voltage circuits of the third sub-peripheral circuit layer comprise first low-voltage circuits on the first surface of the third semiconductor substrate and second low-voltage circuits on the second surface of the third semiconductor substrate.

20. An electronic system comprising:
a peripheral circuit structure and a cell array structure comprising a first cell array region, a second cell array region, and a connection region between the first cell array region and the second cell array region on the peripheral circuit structure; and
a controller electrically connected to a semiconductor device through an input/output pad and configured to control the semiconductor device,
wherein the cell array structure comprises:
a buried insulating pattern in the connection region, the buried insulating pattern comprising a first side surface and a second side surface facing each other in a first direction and a third side surface connecting the first side surface and the second side surface;
a stack comprising conductive patterns stacked in a vertical direction in the first cell array region, the second cell array region, and the connection region, each conductive pattern of the conductive patterns comprising a horizontal portion parallel to the first direction and a pad portion inclined with respect to the horizontal portion; and
cell contact plugs respectively connected to the pad portions of the conductive patterns,
wherein the pad portion of each conductive pattern of the conductive patterns is on the first side surface of the buried insulating pattern, the second side surface of the buried insulating pattern, and the third side surface of the buried insulating pattern.
